(19) United States
(12) Patent Application Publication
(10) Pub. No.: US 2026/0162949 A1
(43) Pub. Date: Jun. 11, 2026

(54) Plasma Processing Device With Imaging Sensor

(71) Applicant: PLASMAPP CO., LTD., Daejeon (KR)

(72) Inventors: Youbong LIM, Daejeon (KR); Jeonghoon LEE, Daejeon (KR)

(73) Assignee: PLASMAPP CO., LTD., Daejeon (KR)

(21) Appl. No.: 19/413,979

(22) Filed: Dec. 9, 2025

(30) Foreign Application Priority Data
Dec. 10, 2024 (KR) 10-2024-0182315

(51) Int. Cl. H01J 37/32

(52) U.S. Cl. CPC H01J 37/32935; H01J 37/3299

(57) ABSTRACT

According to an embodiment of the present disclosure, a plasma processing device for acquiring an image of an object to be processed is disclosed. The plasma processing device comprises: a chamber configured to accommodate the object to be processed; a power supply configured to generate plasma inside the chamber; an imaging sensor configured to acquire a surface image of the object to be processed; and a controller configured to control a capturing operation of the imaging sensor for acquiring the surface image of the object to be processed, according to an operation of the plasma processing device, and wherein the controller determines a time period of plasma processing for the accommodated object to be processed, using one or more surface images corresponding to the object to be processed.

### CROSS-REFERENCE TO RELATED APPLICATIONS

This application claims priority to and the benefit of Korean Patent Application No. 10-2024-0182315filed in the Korean Intellectual Property Office on DECEMBER 10, 2024, the entire contents of which are incorporated herein by reference.

### TECHNICAL FIELD

The present disclosure relates to a plasma processing device and more specifically a plasma processing device comprising an imaging sensor.

### BACKGROUND ART

In the modern medical field, ongoing research is being conducted to improve the success rate and biocompatibility of implants. In particular, implant surface treatment technology plays a key role, after implantation, in bonding with biological tissue and preventing infection.

Conventional implant surface treatment methods have used techniques such as chemical etching, mechanical polishing, and particle blasting, but these methods have limitations in forming surface microstructures and have the problem of not sufficiently enhancing bioactivity.

Plasma technology is emerging as an innovative alternative that can overcome the limitations of such implant surface treatment techniques, and has the advantages of forming nano-level microstructures on the implant surface and uniformly coating bioactive materials. In particular, a plasma treatment in a vacuum state is attracting attention as a next-generation implant surface treatment technology because it can effectively modify surface properties without changing the chemical composition of the implant material.

To improve the biocompatibility and osseointegration performance of implants, the chemical composition of the surface must be optimized, and plasma technology is evaluated as the most promising technology that can meet these requirements. Additionally, plasma treatment can increase antibacterial properties and reduce the risk of infection after implant surgery, thereby further highlighting its importance in the medical field.

### Citation List

### Patent Literature

Patent Literature 1 Korean Patent No. 10-2690522

### SUMMARY OF THE INVENTION

The present disclosure has been made in an effort to efficiently perform surface treatment on an object to be processed by using an image acquired from an imaging sensor in a plasma processing device including the imaging sensor.

Note that the technical problem to be solved by the present disclosure is not limited to the above-described problem, and various technical problems may be included within the scope apparent to one skilled in the art from the following description.

According to an embodiment of the present disclosure, a plasma processing device for acquiring an image of an object to be processed is disclosed. The plasma processing device includes a chamber configured to accommodate the object to be processed; a power supply configured to generate plasma inside the chamber; an imaging sensor configured to acquire a surface image of the object to be processed; and a controller configured to control a capturing operation of the imaging sensor for acquiring the surface image of the object to be processed, according to an operation of the plasma processing device; and the controller determines a time period of plasma processing for the accommodated object to be processed, using one or more surface images corresponding to the object to be processed.

In one embodiment, the chamber includes a drivable chamber tube, at least one surface of the chamber has a light-transmitting property, and the imaging sensor is provided outside the chamber to acquire the surface image of the object to be processed in the chamber.

In one embodiment, the imaging sensor includes a filter configured to transmit light of a predetermined wavelength; a light source configured to irradiate light toward the object to be processed to enhance contrast of the object to be processed being captured, the light source irradiating light corresponding to a predetermined wavelength; a first imaging sensor configured to acquire a first target image including the object to be processed; and a second imaging sensor configured to acquire a second target image that is an enlarged view of a target region in the first target image.

In one embodiment, the plasma processing device further includes a driving unit configured to move the imaging sensor to a target location so that the imaging sensor acquires a target image including the object to be processed; and a display configured to display the acquired surface image or an analysis result of the surface image, by using the controller.

In one embodiment, the controller controls the capturing operation of the imaging sensor such that at least one of a pre-image of the object to be processed at a time point before plasma is generated by the power supply and at least one of a post- image of the object to be processed that has been plasma-processed by the plasma generated by the power supply are respectively acquired.

In one embodiment, the chamber is provided such that one surface of the chamber is at least partially open, and the controller controls the capturing operation of the imaging sensor such that at least one image at a time point before the opening of the chamber and at least one image at a time point after the opening of the chamber are respectively acquired.

In one embodiment, the controller controls the capturing operation of the imaging sensor such that images per time unit are acquired based on a predetermined time unit reference, during a process in which the plasma generated by the power supply is plasma-processing the object to be processed, and controls a plasma processing procedure of the object to be processed according to the generation of the plasma, based on the images per time unit.

In one embodiment, the controller generates a correction value for compensating for an error in surface measurement for the object to be processed, which occurs due to physical damage to the chamber or contamination of the chamber, by comparing the surface of the object to be processed in the image at the time point before the opening of the chamber and the surface of the object to be processed in the image at the time point after the opening of the chamber, and calculates an amount of impurities on the object to be processed prior to the plasma processing of the object to be processed, using the correction value.

In one embodiment, the controller generates a measurement result including an impurity removal state for the object to be processed, plasma discharge characteristics, and plasma reaction characteristics during the plasma processing procedure of the object to be processed, from the images per time unit acquired based on the predetermined time unit, and controls the plasma processing procedure of the object to be processed using the measurement result.

In one embodiment, the controller determines whether to additionally perform a vacuum formation process for a plasma reaction in an isolation space that isolates the accommodated object to be processed from an external environment, using at least one of the plasma discharge characteristics and the plasma reaction characteristics.

In one embodiment, the controller generates a measurement result including an impurity removal state for the object to be processed from the images per time unit corresponding to the object to be processed, and determines whether to resume or complete the plasma processing procedure of the object to be processed using the measurement result.

In one embodiment, the imaging sensor acquires a plurality of images corresponding to the object to be processed during a time period of the plasma processing for the object to be processed in the chamber, and the controller determines an amount of change in a surface of the object to be processed according to the plasma processing using the plurality of images, and dynamically determines a time period of the plasma processing for the object to be processed within an isolation space that isolates the accommodated object to be processed from an external environment, using the determined amount of change in the surface.

In one embodiment, the imaging sensor includes a first imaging sensor and a second imaging sensor, the first imaging sensor and the second imaging sensor are disposed at mutually opposing positions with respect to an isolation space that isolates the accommodated object to be processed from an external environment within the plasma processing device, to acquire a front image and a rear image of the object to be processed, and the controller integrates the front image and the rear image to generate a measurement result regarding the object to be processed.

In one embodiment, the controller determines a target region in the first target image from the first target image including the object to be processed acquired from the first imaging sensor, using a pretrained object detection model, and determines a placement location of the second imaging sensor within the plasma processing device or an orientation angle of the placed second imaging sensor, based on the target region.

In one embodiment, the controller generates an object detection result corresponding to the object to be processed from an image received from the imaging sensor, using a pretrained object detection model, and determines a placement location of the imaging sensor within the plasma processing device or an orientation angle of the placed imaging sensor, using the object detection result.

In one embodiment, the controller determines plasma discharge characteristics indicating an area where plasma is discharged within an image, using the image received from the imaging sensor during the plasma processing procedure for the object to be processed, and determines an amount of impurities included in the object to be processed or determines that a vacuum condition of the plasma processing is not satisfied, based on a time taken for a spatial distribution of light by the plasma to expand within the image, and the plasma discharge characteristics are determined based on the spatial distribution of light by the plasma generated on a surface of the object to be processed within the image.

In one embodiment, the controller determines plasma reaction characteristics indicating a characteristic of light generated by the plasma, using a color value corresponding to the plasma in the image received from the imaging sensor during the plasma processing procedure for the object to be processed.

In one embodiment, the imaging sensor includes a filter configured to extract light corresponding to a predefined wavelength to determine plasma reaction characteristics of the plasma processing of the object to be processed and to determine chemical features of a surface of the object to be processed, and the controller determines plasma reaction characteristics indicating a characteristic of light generated by the plasma, using a wavelength acquired through the filter during the plasma processing procedure for the object to be processed.

In one embodiment, the imaging sensor includes a thermal imaging camera, and the controller controls the thermal imaging camera acquiring a temperature and a temperature distribution of the object to be processed during the plasma processing procedure for the object to be processed.

In one embodiment, the plasma processing device further includes a display configured to output the measurement result; wherein the display displays a first object representing the object to be processed, a second object representing a surface of the object to be processed prior to the plasma processing, and a third object representing a surface of the object to be processed after the plasma processing, and connects at least one of the second object and the third object with the first object by displaying a location of the at least one of the second object and the third object on the first object.

The plasma processing device according to one embodiment of the present disclosure can efficiently perform surface treatment on the object to be processed by using the image acquired from the imaging sensor.

Note that the effects of the present disclosure are not limited to the above-described effects, and various effects may be included within the scope apparent to one skilled in the art from the following description.

### BRIEF DESCRIPTION OF THE DRAWINGS

FIG. 1 is a configuration diagram for illustrating components included in a plasma processing device according to one embodiment of the present disclosure.

FIG. 2 is a schematic diagram for illustrating an internal structure of the plasma processing device according to one embodiment of the present disclosure.

FIG. 3 is a schematic diagram for illustrating movement of an imaging sensor of the plasma processing device according to one embodiment of the present disclosure.

FIG. 4 is a schematic diagram for illustrating a process for acquiring an image in the plasma processing device according to one embodiment of the present disclosure.

FIG. 5 is a view for illustrating an example of an image acquired from the plasma processing device according to one embodiment of the present disclosure.

FIG. 6 is a view for illustrating an example of an image acquired from the plasma processing device during a surface treatment process by the plasma processing device according to one embodiment of the present disclosure.

FIG. 7 is a view for illustrating an example of the plasma processing device according to one embodiment of the present disclosure and objects output by the plasma processing device.

### DETAILED DESCRIPTION

Various embodiments will be now described with reference to the drawings. In the present specification, various descriptions are presented for understanding of the present disclosure. However, it is apparent that these embodiments can be implemented without the specific descriptions.

The term "or" in the present specification is intended to mean an inclusive "or" rather than an exclusive "or." That is, unless otherwise specified or clear from the context, a sentence "X uses A or B" is intended to mean one of the natural inclusive substitutions. That is, the sentence "X uses A or B" may be applied to any of the case where X uses A, the case where X uses B, or the case where X uses both A and B. Further, it should be understood that the term "and/or" used in the present specification designates and includes all available combinations of one or more items among enumerated related items.

Additionally, the terms "includes (comprises)" and/or "including (comprising)" should be understood to imply the presence of the respective features and/or components. However, it should be understood that the terms "includes (comprises)" and/or "including (comprising)" do not exclude the presence or addition of one or more other features, components, and/or groups thereof. Further, unless otherwise specified or in cases where it is not clear from the context to designate a singular form, the singular form in the present specification and claims should be interpreted as meaning "one or more" in general.

And, the term "at least one of A or B" should be interpreted to mean "a case including only A," "a case including only B," and "a case in which A and B are combined."

The description of the disclosed exemplary embodiments is provided to enable a person skilled in the art to implement or use the present disclosure. Various modifications to the exemplary embodiments will be apparent to one skilled in the art. The general principles defined herein may be applied to other exemplary embodiments without departing from the scope of the present disclosure. Thus, the present disclosure is not limited to the exemplary embodiments presented herein. The present disclosure is to be interpreted in the broadest scope consistent with the principles and novel features presented herein.

In the present disclosure, an object to be processed may mean a target of surface treatment according to a plasma processing procedure performed by a plasma processing device. For example, the object to be processed may include an implant corresponding to an artificial tooth for replacing a patient's lost tooth. Specifically, an implant may include an artificial tooth root that serves as the root of an artificial tooth, an abutment that serves as the pillar of the artificial tooth, and a crown that is a head portion of the artificial tooth.

In the present disclosure, the expression "surface treating an object to be processed" may mean exposing the implant to plasma generated by a plasma processing device before implanting the implant into a patient's gum, in order to sterilize the implant and wash away impurities on the implant surface.

In the present disclosure, the expression "surface treatment(treatment of the surface)" may mean a part of processes within a plasma processing procedure, which is performed by the plasma processing procedure. Specifically, "surface treatment" may mean a process performed by exposing the surface of an object to be processed to plasma generated according to a plasma processing procedure. Therefore, in the present disclosure, the expressions "surface treatment," "plasma processing," and "plasma processing procedure" may have corresponding meanings and may be used interchangeably.

In the present disclosure, the plasma processing device may be a device that uses electricity and includes a plurality of electrodes corresponding to conductors with good electrical conductivity for conducting current in an electric circuit.

In the present disclosure, plasma may correspond to generation of discharge energy, such as plasma discharge, arc discharge, or dielectric barrier discharge (DBD), due to a potential difference between electrodes.

In the present disclosure, a user may refer to an entity that uses and/or controls a plasma processing device. For example, a user may be a professional who manufactures implants or a medical professional who treats patients.

In the present disclosure, the terms "plasma," "plasma discharge," and/or "plasma generation" may have corresponding meanings and may be used interchangeably.

In the present disclosure, the terms "plasma processing" and/or "surface treatment" may have corresponding meanings and may be used interchangeably.

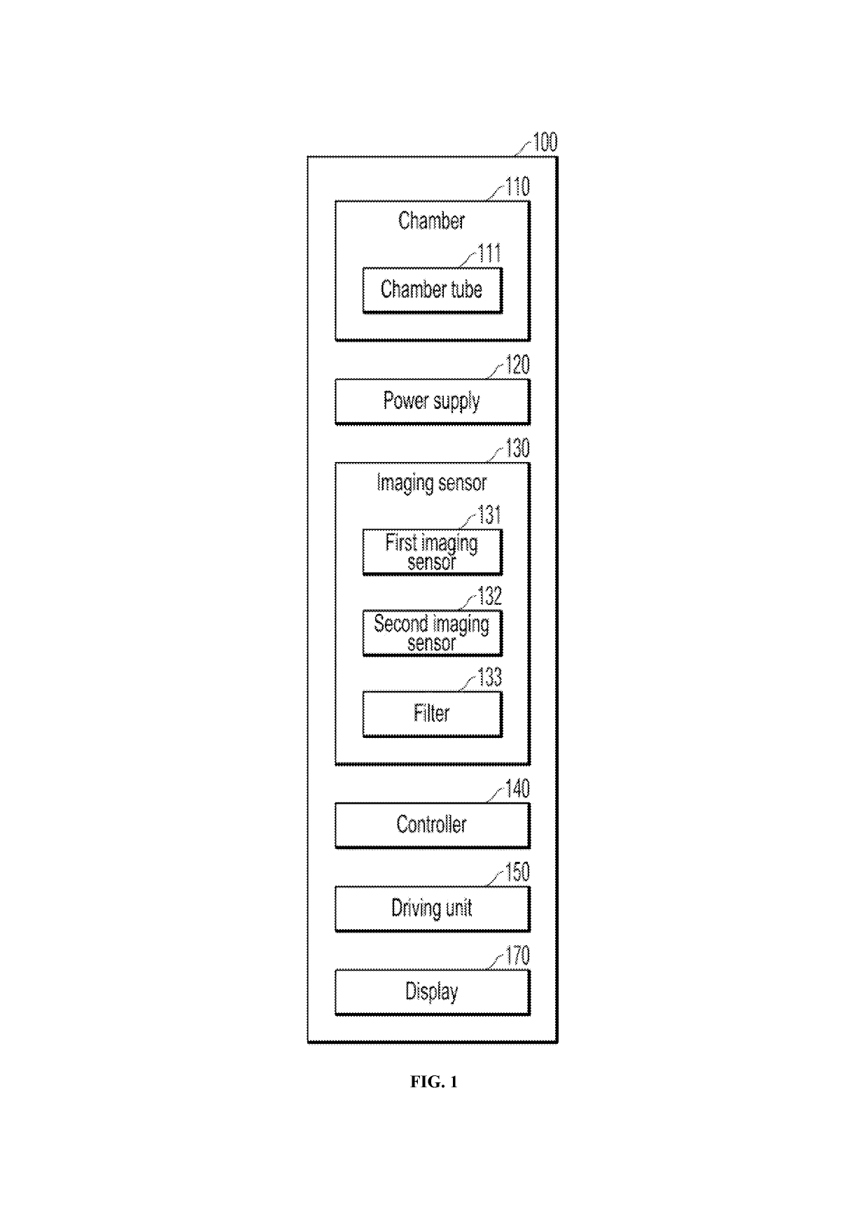

FIG. 1 is a configuration diagram for illustrating components included in a plasma processing device according to one embodiment of the present disclosure.

Referring to FIG. 1, a plasma processing device 100 that acquires an image of an object to be processed is disclosed.

In one embodiment, the plasma processing device 100 may include a chamber 110 that accommodates an object to be processed, a power supply 120 that generates plasma inside the chamber 110, and an imaging sensor 130 that acquires a surface image of the object to be processed.

In one embodiment, the chamber 110 may refer to a space provided in a portion of the plasma processing device 100 and exposed to the outside of the plasma processing device 100.

In one embodiment, the chamber 110 may be configured such that at least a portion of the chamber 110 is exposed to the outside to allow a user to place the object to be processed into, and retrieve it from, an isolation space within the chamber 110.

In one embodiment, the chamber 110 may include an isolation space that accommodates the object to be processed and isolates it from the external environment.

In one embodiment, at least one surface of the chamber 110 may have a light-transmitting property to allow a user to observe an operation of the plasma processing device 100 from outside the chamber 110.

In one embodiment, the chamber 110 may include a chamber tube 111 for physically blocking the chamber 110 from the outside so that plasma is not exposed to the outside when the plasma processing device 100 is operating.

In one embodiment, the chamber tube 111 may be, for example, a cylindrical structure that is formed at least in part of a transparent material, and may perform a function of exposing an isolation space inside the chamber 110 to the outside or blocking it from the outside by changing its position inside the chamber 110.

In one embodiment, the chamber tube 111 may move to change its position within the chamber 110. For example, the chamber tube 111 may move to change its position at upper and lower portions of the chamber 110. When the chamber tube 111 is located at the upper portion of the chamber 110, the chamber 110 may be in an open state, and when the chamber tube 111 is located at the lower portion of the chamber 110, the chamber 110 may be in a closed state.

In one embodiment, when the chamber 110 is in an open state, the user can place the object to be processed in the isolation space inside the chamber 110, and when the chamber 110 is in a closed state, the user cannot access the inside of the chamber 110.

In one embodiment, the chamber tube 111 may move between a closed position in which the isolation space of the chamber 110 is in a closed state and an open position in which the isolation space is in an open state by moving relative to the chamber 110.

In one embodiment, the chamber tube 111 may be driven to allow the user to place and retrieve the object to be processed within the chamber 110. For example, the chamber tube 111 may be opened to accommodate the object to be processed inside the chamber 110 and closed to irradiate the object to be processed with plasma.

In one embodiment, surface treatment of the object to be processed may be performed when the chamber 110 is completely closed by the chamber tube 111 so that the plasma is not exposed to the outside to protect the user from the plasma. Then, after the surface treatment of the object to be processed is completed, the chamber tube 111 can be opened again so that the user can retrieve the object to be processed.

In one embodiment, the power supply 120 may be a device that transfers electrical energy to cause the plasma processing device 100 to generate plasma. For example, the power supply 120 may be a power supply.

In one embodiment, the power supply 120 may include a function of adjusting impedance so as to control power in consideration of a frequency of the supplied power. In one embodiment, the power supply 120 may include a function of detecting an excessive current flowing within the plasma processing device 100 and cutting off the supplied power.

In one embodiment, the plasma processing device 100 may cause plasma to be generated inside the chamber 110 by generating electrical energy in the power supply 120 and transferring the generated electrical energy to the chamber 110. Accordingly, surface treatment of the object to be processed located inside the chamber 110 may be performed as the plasma is generated.

In one embodiment, the imaging sensor 130 may refer to any type of sensor that performs an imaging operation for capturing or acquiring a surface image of an object to be processed within the chamber 110. In one embodiment, the imaging sensor 130 may refer to a device that converts light into an electrical signal to generate a digital image. For example, the imaging sensor 130 may include a CCD (Charge-Coupled Device) sensor, a CMOS (Complementary Metal-Oxide-Semiconductor) sensor, a Foveon sensor, an infrared sensor, a ToF (Time-Of-Flight) sensor, a lidar sensor, an EMCCD (Electron Multiplying CCD) sensor, an sCMOS (Scientific CMOS) sensor, an organic CMOS sensor, and the like.

In one embodiment, the imaging sensor 130 may include one or more cameras provided outside the chamber 110 to acquire a surface image of the object to be processed within the chamber 110.

In one embodiment, the imaging sensor 130 may include a first imaging sensor 131 that acquires a first target image including an object to be processed and a second imaging sensor 132 that acquires a second target image that is an enlarged view of a target region in the first target image. For example, the target image may be used to denote an image including an object to be processed that is acquired by the imaging sensor 130. For example, the target region may be used to denote a region within an image (or target image) where an impurity is present.

In one embodiment, when the object to be processed is an implant, the first target image may include an entire region of the implant, and the second target image may include a partial region of the implant (for example, a region corresponding to an impurity).

In one embodiment, the imaging sensor 130 may include a filter 133 that transmits light of a predetermined wavelength.

In one embodiment, the filter 133 may transmit a wavelength range that includes light corresponding to plasma, so as to detect whether light corresponding to plasma is generated.

In one embodiment, the filter 133 may extract light corresponding to a predetermined wavelength to determine plasma reaction characteristics and to determine chemical features of a surface of the object to be processed. For example, when the object to be processed has an impurity on its surface, a region with an impurity and a region with no impurity may reflect light of different wavelengths due to differences in chemical properties. Alternatively, the chemical properties of the object to be processed may change before and after surface treatment. Accordingly, the wavelength of light reflected from the object to be processed before and after surface treatment may also be different. The chemical features of the object to be processed may be determined through the filter by using the difference in wavelength resulting from the listed chemical changes.

In one embodiment, the controller 140 may control the overall operation of the plasma processing device 100.

In one embodiment, the controller 140 may determine plasma reaction characteristics indicating a characteristic of light generated by plasma, using a wavelength acquired through the filter 133 during the plasma processing procedure for the object to be processed.

The plasma reaction characteristics may correspond to different wavelengths of light generated depending on the physical and/or chemical properties of the surface of the object to be processed when the object to be processed is surface treated by plasma. For example, the plasma reaction characteristics may correspond to different wavelengths of light generated depending on whether the surface of the object to be processed includes a region where an impurity is present.

In one embodiment, light generated by the plasma when an impurity is present may have a relatively longer wavelength than light generated when no impurity is present, because the impurity absorbs energy of the plasma upon contact with the plasma. For example, when no impurity is present, the light corresponding to the plasma may correspond to high-energy, short-wavelength light, such as violet or blue light. Therefore, depending on an impurity concentration, an area of a region where the impurities are distributed, and the like, the plasma loses energy due to the impurities, and accordingly, the wavelength of the light corresponding to the plasma becomes longer, so that the light may include red or yellow light, or the like.

In one embodiment, the imaging sensor 130 may include a light source that irradiates light toward the object to be imaged to enhance contrast of the object to be processed being captured. For example, the light source may irradiate light corresponding to a predetermined wavelength.

In one embodiment, when the light source irradiates light, the contrast depending on a shape of the object to be processed may be enhanced. For example, the object to be processed may have a structure including threads, grooves, flat surfaces, and the like. Accordingly, when the light source irradiates light an image including the object to be processed acquired from the imaging sensor 130 may display the threads of the object to be processed as the brightest, the flat surface as the next brightest, and the grooves as the darkest.

In one embodiment, when the light source irradiates light, the image acquired from the imaging sensor 130 may include the object to be processed in which a difference between a region with an impurity and a region with no impurity is more distinct.

In one embodiment, when the light source irradiates light, even if impurities are not visible to the naked eye, an image acquired after surface treatment of the surface on which impurities are present may include a surface of the object to be processed whose contrast has changed, compared with an image acquired before the surface treatment, due to a change in reflectance of the surface of the object to be processed caused by the surface treatment.

In one embodiment, the imaging sensor 130 may include imaging sensors 131 and 132 for image acquisition, such as cameras, a filter and/or a light source.

In one embodiment, the plasma processing device 100 may further include a controller 140 that controls a capturing operation of the imaging sensor 130 for acquiring the surface image of the object to be processed, according to an operation of the plasma processing device 100.

In one embodiment, the controller 140 may control the imaging sensor 130 to acquire an image of the object to be processed at a predefined time point. For example, the controller 140 may control the capturing operation of the imaging sensor 130 such that at least one of a pre-image of the object to be processed at a time point before plasma is generated by the power supply 120 and at least one of a post-image of the object to be processed that has been plasma-processed by the plasma generated by the power supply 120 are respectively acquired.

In one embodiment, the imaging sensor 130 may acquire a plurality of images corresponding to the object to be processed during a time period of plasma processing of the object to be processed within the chamber 110. Then, the controller 140 may dynamically determine an amount of change in the surface of the object to be processed due to the plasma processing, and a plasma processing time for the object to be processed by using the plurality of images. For example, the controller 140 may determine an amount of change per unit time in impurities on the surface of the object to be processed, based on an area and/or a color of impurities included on the surface of the object to be processed through the plurality of images. The controller 140 may determine a plasma processing time (for example, remaining processing time) for the object to be processed for removing impurities, based on the amount of change in impurities on the object to be processed.

In one embodiment, the controller 140 may include a computing device that executes a program stored in a computer-readable storage medium.

In one embodiment, the controller 140 may control overall operations that are performed by the plasma processing device 100, such as movement of the chamber tube 111 and whether the power supply 120 supplies power, in addition to the capturing operation of the imaging sensor 130.

In one embodiment, the plasma processing device 100 may include an imaging sensor driving unit 150 that moves the imaging sensor 130 to a target position so that the imaging sensor 130 acquires a target image including the object to be processed.

In one embodiment, the imaging sensor driving unit 150 may be connected to the imaging sensor 130 to generate power to control a change in position of the imaging sensor 130. For example, the imaging sensor driving unit 150 may include a motor and generate power using the motor. For example, the driving unit 150 may generate power by using a solenoid that utilizes electromagnetic induction. For example, the driving unit 150 may include a piezoelectric actuator that generates power by applying a piezoelectric voltage. For example, the driving unit 150 may include a hydraulic driving unit that utilizes fluid pressure. For example, the driving unit 150 may include a pneumatic driving unit that moves the imaging sensor 130 by using compressed air. For example, the driving unit 150 may include a pneumatic driving unit that moves the imaging sensor 130 by using elasticity of a spring. For example, the driving unit 150 may include a magnetic actuator that moves the imaging sensor 130 by using a magnetic force of a magnet. For example, the driving unit 150 may move the imaging sensor 130 by using a shape-memory alloy actuator that utilizes the characteristic of a metal returning to its original shape at a specific temperature. For example, the driving unit 150 may move the imaging sensor 130 by using a crank system that uses a gear for converting rotational motion into linear motion and a mechanical link for amplifying force. For example, the driving unit 150 may include an electromagnetic induction-based driving unit that utilizes force generated by electromagnetic induction.

In one embodiment, the plasma processing device 100 may determine a target position of the imaging sensor 13 for acquiring an optimal target image according to a position, a size, and the like of the object to be processed. When the target position is determined, the imaging sensor driving unit 150 may move the imaging sensor 130 to the target position. For example, the target location may be used to denote a location of the imaging sensor 130 for acquiring an image corresponding to the object to be processed (for example, a target image).

In one embodiment, the plasma processing device 100 may further include a display 170 that displays the acquired surface image or an analysis result of the surface image by using the controller 140.

In the present disclosure, the display 170 may include at least one of a liquid crystal display (LCD), a thin film transistor-liquid crystal display (TFT LCD), an organic light-emitting diode (OLED), a flexible display, a 3D display, and an e-ink display. The display 170 displays (outputs) data processed by the controller 140. Specifically, the display 170 can display (output) an image acquired through the imaging sensor 130.

In the present disclosure, the specific operation methods and implementation examples of the plasma processing device 100 and the components of the plasma processing device 100 will be described in detail with reference to the drawings below.

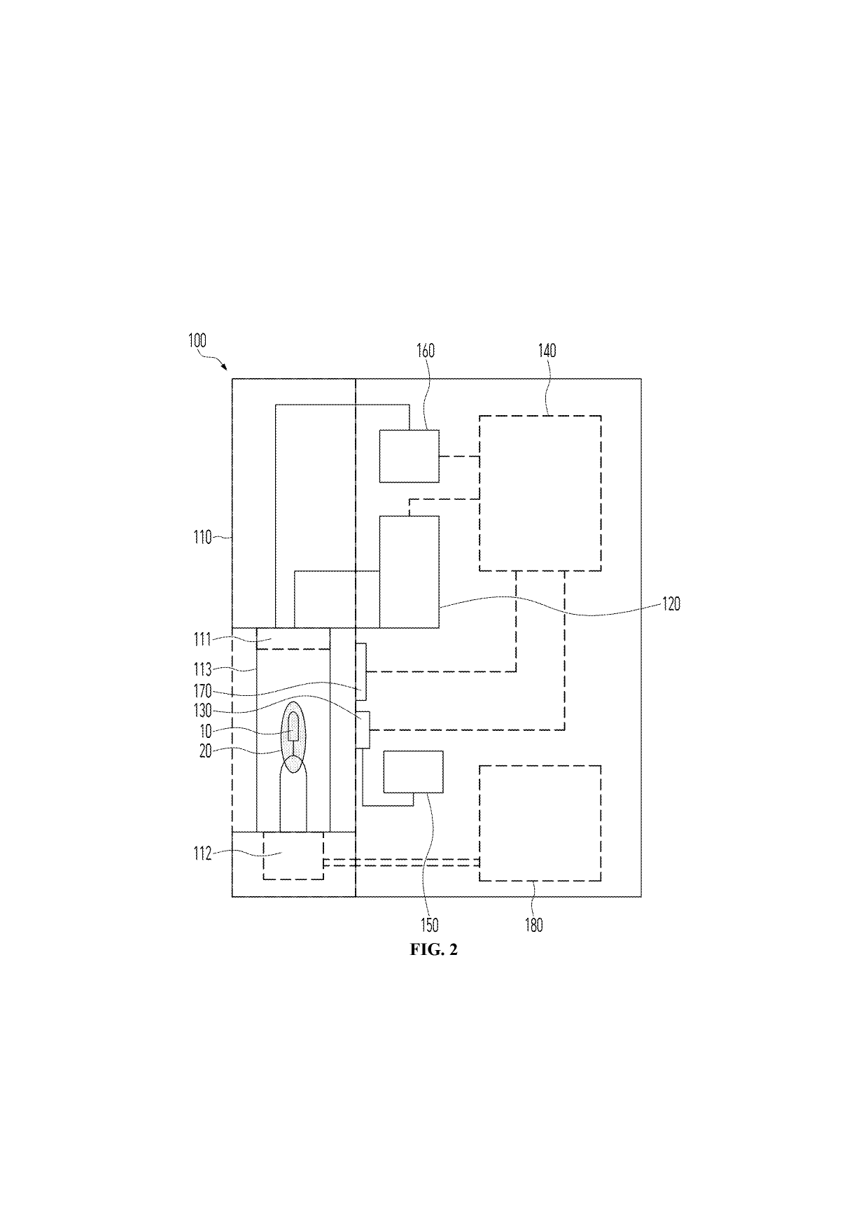

FIG. 2 is a schematic diagram for illustrating an internal structure of the plasma processing device according to one embodiment of the present disclosure.

Referring to FIG. 2, a side cross-sectional side view of the plasma processing device 100 is disclosed, showing the disposed positions of the components included in the plasma processing device 100 within the plasma processing device 100 and the relationships between the components.

In one embodiment, the plasma processing device 100 may include a chamber 110 located on one surface (for example, a front surface) of the plasma processing device 100.

In one embodiment, the chamber 110 may include a chamber tube 111, accommodate an object to be processed 10 in an internal isolation space, and generate plasma 20 for the object to be processed.

In one embodiment, the power supply 120 may generate electrical energy and transfer the generated electrical energy to an electrode 113 so that the plasma 20 is generated between the electrode 113 and a ground electrode 112.

In one embodiment, the electrode 113 and the ground electrode 112 are an electrode pair for generating the plasma 20, and a voltage may be applied to one (for example, the electrode 113) of the electrode pair. The electrode pair may form an electric field between the electrodes and ionize gas molecules to generate plasma.

In one embodiment, the electrode 113 and the ground electrode 112 may have a material of metal or alloy. For example, the electrode 113 and the ground electrode 112 may be made of a metal material (for example, copper, aluminum, stainless steel, tungsten, or the like).

In one embodiment, the chamber 110 may further include a fixing member for fixing the object to be processed 10 to the internal isolation space. For example, the fixing member may fix the object to be processed 10 at a position inside the chamber 110 by coupling the object to be processed 10 to the top of the fixing member. In the example in FIG. 2, the fixing member for positioning the object to be processed 10 in a fixed state is illustratively shown at the bottom of the object to be processed 10.

In one embodiment, the chamber 110 may include the electrode 113 and the ground electrode 112 for generating plasma. Plasma may be generated by the energy difference between the electrode 113 and the ground electrode 112.

In one embodiment, the chamber 110 may include a vacuum pump 180 for creating a vacuum inside the chamber 110. When a vacuum is created inside the chamber 110 by the vacuum pump 180, the plasma processing device 100 can precisely control plasma discharge, thereby performing surface treatment with plasma more accurately and delicately.

In one embodiment, the controller 140 may determine a plasma discharge characteristic, which indicate a region where plasma is discharged in the image, by using an image received from the imaging sensor 130 during plasma processing of the object to be processed 10. The plasma discharge characteristic may be determined based on a spatial distribution 20 of light by plasma generated on a surface of the object to be processed 10 within the image.

In one embodiment, the controller 140 may determine an amount of impurity presented on the object to be processed 10, based on a time taken for the spatial distribution 20 of light by the plasma to expand within the image.

In one embodiment, the time taken for the spatial distribution 20 of light by the plasma to expand and the amount of impurity presented on the object to be processed 10 may be inversely proportional. Accordingly, the controller 140 may determine the amount of impurity presented on the object to be processed 10 by calculating a rate of change per hour of the spatial distribution 20 of light by plasma. For example, the controller 140 may determine that the amount of impurity presented on the object to be processed 10 is small when the rate of change per hour of the spatial distribution 20 of light by plasma is high, and may determine that the amount of impurity presented on the object to be processed 10 is large when the rate of change per hour of the spatial distribution 20 of light by plasma is low. For example, the rate of change per hour of the spatial distribution 20 of light by plasma and the amount of impurity presented on the object to be processed 10 may have a negative correlation with each other.

In one embodiment, the light may be visible light observable by the user. In one embodiment, at least a portion of the chamber 110 is provided with a transparent member, so that the user can visually check the plasma without a separate notification device. By visually checking whether plasma is generated and the intensity of the plasma, it is possible to achieve an effect that the user can intuitively check whether the device is operating and the intensity of the plasma for surface treatment.

In one embodiment, the plasma processing device 100 may control a plasma generation time according to the amount of impurity, and may create a vacuum inside the chamber 110 to quantitatively control the plasma generation time.

Creating a vacuum inside the chamber 110 to quantitatively control the plasma generation time may mean that the efficiency of surface treatment by plasma may differ depending on the gas state inside the chamber 110, and thus, to prevent this, the gas state inside the chamber 110 is made to be the same (for example, a vacuum state) as much as possible.

In one embodiment, as the plasma processing procedure progresses, the gas state inside the chamber 110 may vary. The method for creating a vacuum according to variations in the gas state will be described with reference to the drawings below.

In one embodiment, the plasma processing device 100 may include the vacuum pump 180 for creating a vacuum inside the chamber 110. The vacuum pump 180 may lower pressure inside the chamber 110 and create a vacuum inside the chamber 110 by discharging the gas inside the chamber 110 to the outside of the chamber 110.

In one embodiment, the plasma processing device 100 may move the chamber tube 111 to a position corresponding to a closed state to create a vacuum inside the chamber 110. When the chamber tube 111 is moved to a position corresponding to a completely closed state (for example, a closed position), the inside of the chamber 110 may be completely sealed from the outside of the chamber 110.

In one embodiment, the plasma processing device 100 may include a chamber tube driving unit 160 for changing the position of the chamber tube 111. The chamber tube driving unit 160 may be connected to the chamber tube 111 and may move the chamber tube 111. For example, the chamber tube driving unit 160 may include a motor, and move the chamber tube 111 by generating power using the motor. The driving unit 160 of the chamber tube 111 may move the chamber tube 111 by using at least one of the methods exemplified in relation to the driving unit 150 described above.

In one embodiment, the controller 140 may determine that the vacuum condition within the chamber 110 for plasma processing is not satisfied, based on the time taken for the spatial distribution 20 of light by the plasma to expand within the image. The controller 140 may generate plasma in a state in which no object to be processed 10 exists inside the chamber 110 and observe the time taken for the spatial distribution 20 of light by the plasma to expand. For example, when the inside of the chamber 110 is in a vacuum state, the time taken for the spatial distribution 20 of light by plasma to expand may be constant. Accordingly, the controller 140 may determine that the vacuum condition within the chamber 110 for plasma processing is not satisfied when the time taken for the spatial distribution 20 of light by plasma to expand is different from the time taken for the spatial distribution 20 of light by plasma to expand when the inside is in a vacuum state.

In one embodiment, the controller 140 may acquire a plurality of images to observe the time taken for the spatial distribution 20 of light by plasma to expand within the image, and each of the plurality of images may include time information corresponding thereto.

In one embodiment, when the imaging sensor 130 includes a first imaging sensor 131 and a second imaging sensor 132, the first imaging sensor 131 and the second imaging sensor 132 may be disposed at mutually opposing positions with respect to an isolation space that isolates the accommodated object to be processed 10 from an external environment within the plasma processing device 100. The first imaging sensor 131 and the second imaging sensor 132 may acquire a front image and a rear image of the object to be processed 10.

In one embodiment, the controller 140 can integrate the front image and the rear image to generate a measurement result regarding the object to be processed 10. By integrating the front image and the rear image, the controller 140 may generate an image corresponding to a 360-degree region of the object to be processed.

In one embodiment, the controller 140 may control a change in the position of the imaging sensor 130 by using the imaging sensor driving unit 150. The controller 140 may control the imaging sensor 130 to acquire an image inside the chamber 110.

In one embodiment, the controller 140 may output an image acquired from the imaging sensor 130 and/or an analysis result using the image through the display 170 so that the image and/or the analysis result can be visually displayed to the user.

In one embodiment, the controller 140 controls the overall operations of the imaging sensor 130, the imaging sensor driving unit 150, the chamber tube driving unit 160, the display 170, and the vacuum pump 180, thereby enabling the plasma processing device 100 to perform surface treatment on the object to be processed.

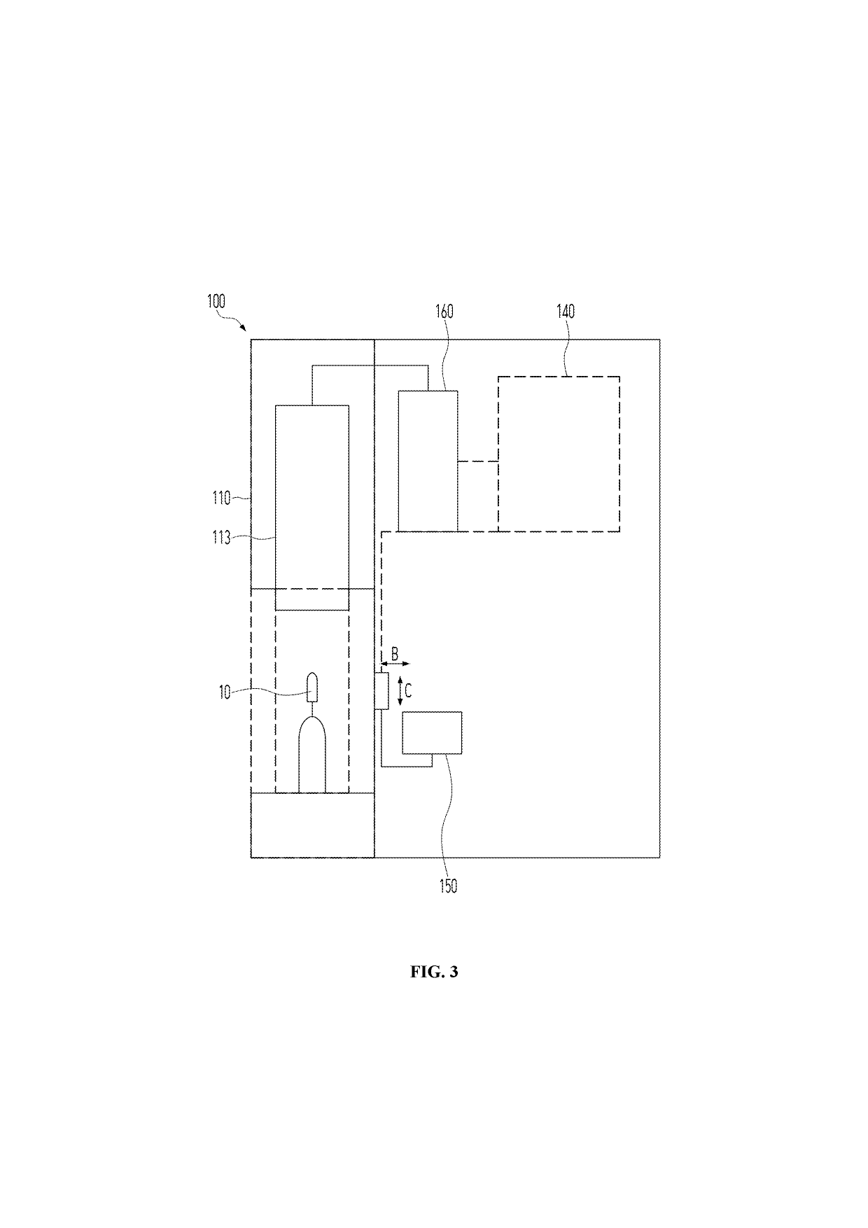

FIG. 3 is a schematic diagram for illustrating movement of an imaging sensor of the plasma processing device according to one embodiment of the present disclosure.

In one embodiment, the chamber 110 may be provided such that one surface of the chamber 110 is at least partially open.

In one embodiment, the chamber 110 may be at least partially opened or closed by the chamber tube driving unit 160 that receives a command from the controller 140. For example, the chamber tube driving unit 160 may move the chamber tube 111 to an open position or a closed position by changing the position of the chamber tube 111 in response to a command from the controller 140.

In one embodiment, the controller 140 may control the capturing operation of the imaging sensor 130 such that at least one image at a time point before the opening of the chamber 110 and at least one image at a time point after the opening of the chamber 110 are respectively acquired.

In one embodiment, the controller 140 may change the imaging sensor 130 from an idle state to a capturing-enabled state when the chamber tube 111 is detected as being in the open or closed position. For example, the controller 140 may determine whether to start capturing of the imaging sensor 130, based on a current position of the chamber tube 111. For example, the controller 140 may put the imaging sensor 130 into the idle state when the chamber tube 111 is in the open position. For example, the controller 140 may put the imaging sensor 130 into the capturing-enabled state when the chamber tube 111 is in the closed position. For example, the controller 140 may perform a state transition of the imaging sensor 130 according to the change in the position of the chamber tube 1110. Accordingly, since the imaging sensor 130 is not always in the capturing-enabled state but can transition to the capturing-enabled state in a situation where actual capturing is performed or in a situation where actual capturing is required, a technical effect of efficiently using the power resources of the imaging sensor 130 can be achieved.

In one embodiment, the imaging sensor 130 may be provided to be movable in a region outside the chamber 110 of the plasma processing device 100.

In one embodiment, the controller 140 may change the position of the imaging sensor 130 by using the imaging sensor driving unit 150.

In one embodiment, the imaging sensor driving unit 150 may move the imaging sensor 130 in a direction of arrow B for changing a distance between the object to be processed 10 and the imaging sensor 130 by moving the imaging sensor 130 in a direction parallel to the ground, or in a direction of arrow C for changing the distance between the object to be processed 10 and the imaging sensor 130 by moving the imaging sensor 130 in a direction perpendicular to the ground, in response to a command from the controller 140 determined according to the position of the object to be processed 10. For example, when the imaging sensor 130 moves in the direction of arrow B, the imaging sensor 130 may approach or move away from the object to be processed 10 in a direction parallel to the object to be processed 10. For another example, when the imaging sensor 130 moves in the direction of arrow C, the imaging sensor 130 may approach or move away from the object to be processed 10 in a direction perpendicular to the object to be processed 10. For example, when the B direction corresponds to left/right, the C direction may correspond to up/down.

In one embodiment, the controller 140 may move the imaging sensor 130 in the B direction to adjust a focus of the object to be processed 10 in the image acquired from the imaging sensor 130. Alternatively, the controller 140 may move the imaging sensor 130 in the B direction to adjust an image size of the object to be processed 10 acquired from the imaging sensor 130. In one embodiment, the controller 140 may move the imaging sensor 130 in the C direction to adjust am angle of the object to be processed 10 shown in the image acquired from the imaging sensor 130.

Since the object to be processed 10 may have a curved shape, the controller 140 may move the position of the imaging sensor 130 in the B direction and/or the C direction to acquire an image that includes the impurity from the front as much as possible, depending on the position of the impurity.

In one embodiment, the imaging sensor driving unit 150 may change an angle at which the imaging sensor 130 views the object to be processed 10, in response to a command from the controller 140 determined according to the position of the object to be processed 10.

In one embodiment, the controller 140 may determine a plasma reaction characteristic, which indicates characteristics of light generated by plasma, by using a color value corresponding to the plasma in an image received from the imaging sensor 130 during the plasma surface processing procedure for the object to be processed 10.

In one embodiment, the characteristics of light generated by plasma may refer to the color, brightness, distribution region, and the like of light corresponding to the plasma.

In one embodiment, the characteristics of light generated by plasma may refer to an amount of change (change in time, region, color, and the like) in at least one of the color, brightness, and distribution region of light corresponding to the plasma.

In one embodiment, the controller 140 may determine plasma reaction characteristics by using the characteristics of light generated by the plasma.

In one embodiment, the imaging sensor 130 may acquire an image including the object to be processed 10 and the plasma 20 during the plasma surface processing procedure for the object to be processed 10. For example, the image may contain a color value corresponding to the plasma 20. For example, the color value may be a value corresponding to general blue, purple, or red.

In one embodiment, the imaging sensor 130 may include a thermal imaging camera. The controller 140 may control the thermal imaging camera that acquires temperatures and a temperature distribution of the object to be processed 10 during the plasma processing procedure for the object to be processed 10.

In one embodiment, the temperature of the object to be processed 10 increases in proportion to the time of the plasma processing procedure, and as the temperature of the object to be processed 10 increases, the thermal imaging camera may acquire an image that includes many regions of a color corresponding to a high temperature of the object to be processed 10.

In one embodiment, when the plasma processing procedure ends, the temperature of the object to be processed 10 decreases, and as the temperature of the object to be processed 10 decreases, the thermal imaging camera may acquire an image that includes many regions of a color corresponding to a low temperature of the object to be processed 10.

In one embodiment, the controller 140 may acquire a color value and a temperature distribution corresponding to the plasma through the image received from the imaging sensor 130. Then, the controller 140 may determine the intensity of plasma to be additionally generated, the time of plasma processing procedure, and the like based on the color value and temperature distribution corresponding to the plasma.

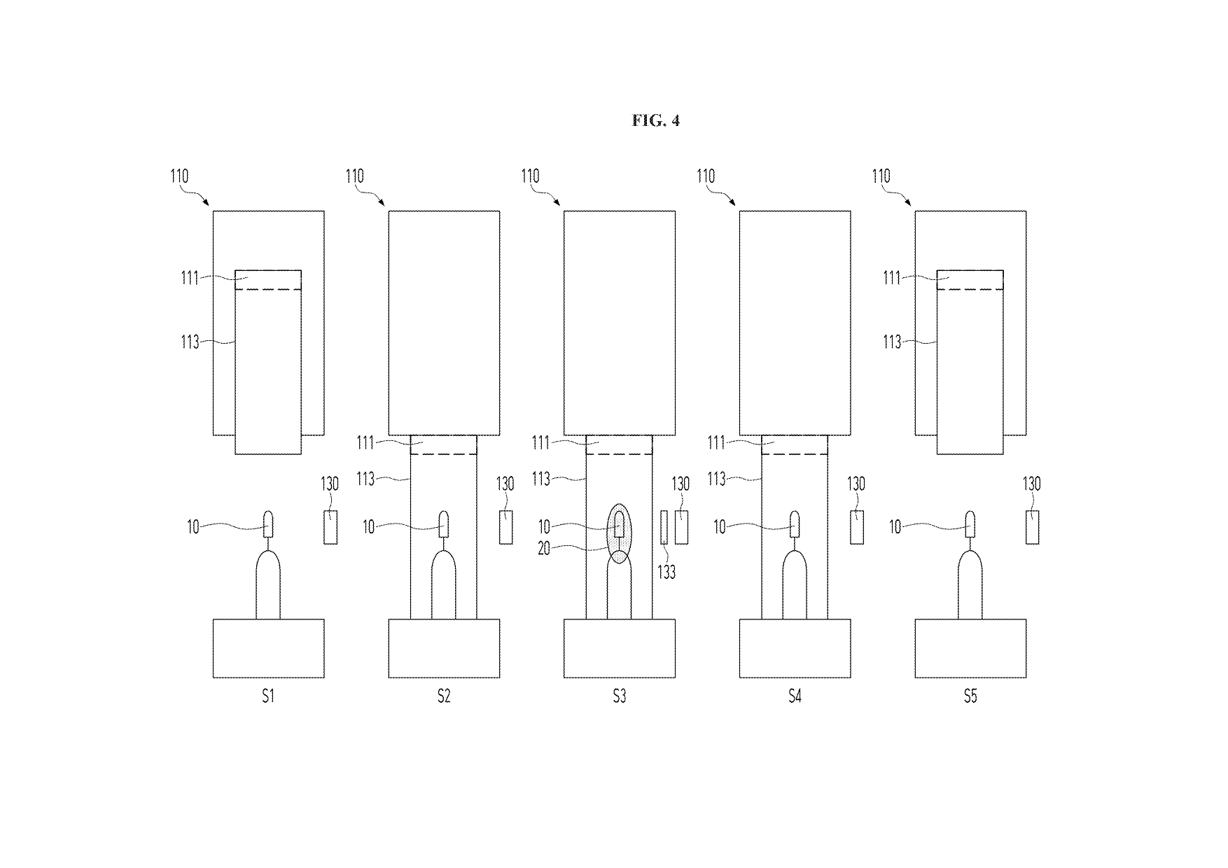

FIG. 4 is a schematic diagram for illustrating a process for acquiring an image in the plasma processing device according to one embodiment of the present disclosure.

Referring to FIG. 4, the chamber 110 that accommodates the object to be processed 10 is disclosed to explain an image acquisition process using the imaging sensor 130 of the plasma processing device 100.

In one embodiment, the controller 110 may control the capturing operation of the imaging sensor 130 such that images per time unit are acquired based on a predetermined time unit reference. The controller 110 may control the plasma processing procedure of the object to be processed according to the generation of plasma, based on the images per time unit.

In one embodiment, the controller 140 may generate a correction value for reducing errors in image review results due to physical damage to the surface of the chamber tube 111, contamination of the chamber tube 111, or the like.

In one embodiment, the correction value may be acquired from a comparison result of an image acquired with the chamber tube 111 positioned in the open position and an image acquired with the chamber tube 111 positioned in the closed position.

In one embodiment, the controller 140 may control the capturing operation of the imaging sensor 130 such that images per time unit are acquired based on the predetermined time unit reference, while the plasma 20 generated by the power supply 120 is plasma-processing the object to be processed 10. The controller 140 may control the plasma processing procedure of the object to be processed 10 according to the generation of the plasma 20, based on the images per time unit.

In one embodiment, the controller 140 may generate a correction value for compensating for an error in surface measurement for the object to be processed 10, which occurs due to physical damage to the chamber 110 or contamination of the chamber 110, by comparing the surface of the object to be processed in the image at the time point before the opening of the chamber 110 and the surface of the object to be processed in the image at the time point after the opening of the chamber 110. Then, the controller 140 may calculate an amount of impurity on the object to be processed 10 prior to the plasma processing of the object to be processed 10, using the correction value.

In the example of FIG. 4, the controller 140 may associate each of operations related to plasma processing of the plasma processing device with a capturing state and/or a capturing mode of the imaging sensor 130. Accordingly, the imaging sensor 130 may be operated to acquire an image(s) in a manner corresponding to the operations of the plasma processing device. Each of the operations of the plasma processing device may be a trigger for changing the capturing operation or capturing mode of the imaging sensor 130. As will be specifically described below, each of the detailed operations of the plasma processing device may be a trigger for changing the state of the imaging sensor 130.

In S1, the chamber tube 111 may be positioned in the open position, and the chamber 110 may be in an open state.

In one embodiment, the controller 140 may change the imaging sensor 130 from an idle state to a first capturing state for capturing a first image corresponding to the object to be processed 10 when the chamber tube 111 is detected as being in the open position. Then, the controller 140 may acquire a first image from the imaging sensor 130 that has been changed to the first capturing state. In one embodiment, when the first image is acquired in S1, the imaging sensor 130 may be switched back to the idle state.

In the present disclosure, the imaging sensor 130 being in an idle state may mean that the imaging sensor 130 is in a state in which it does not acquire an image (for example, in a power-saving mode or a power off), and the imaging sensor 130 being changed to a capturing state may mean that the imaging sensor 130 changes to a state in which it acquires an image.

In S2, the chamber tube 111 may be positioned in the closed position, and the chamber 110 may be in the closed state.

In the example of S2 of FIG. 4, it is shown that the chamber tube 111 moves (for example, in a downward direction) from a state (for example, the open position) where it is at least partially inserted into the chamber 110 to the closed position for creating an isolation space that isolates the object to be processed 10 from the external environment. In one embodiment, the controller 140 may change the imaging sensor 130 from the idle state (or from the first capturing state for capturing a first image) to a second capturing state for capturing a second image corresponding to the object to be processed 10 when the chamber tube 111 is detected as being in the closed position. Then, the controller 140 may acquire a second image from the imaging sensor 130 that has been changed to the second capturing state. In one embodiment, when the second image is acquired in S2, the imaging sensor 130 may be switched back to the idle state.

In one embodiment, the controller 140 may generate a correction value for compensating for an error in impurity measurement for the object to be processed 10, which occurs due to physical damage to the chamber tube 111 and/or contamination of the chamber tube 111, by comparing impurities of the object to be processed 10 in the first image and impurities of the object to be processed in the second image. For example, the controller 140 may acquire in advance values corresponding to physical damage to the chamber tube 111 and/or contamination of the chamber tube 111 by comparing the impurities of the object to be processed 10 in the first image and the impurities of the object to be processed 10 in the second image, and may generate a correction value by using the acquired values. When the same chamber tube 111 is used in the same situation, the controller 140 may accurately measure the impurities of the object to be processed 10 by applying the correction value generated in advance to the acquired image of the object to be processed 10. As described above, the controller 140 may determine what an error caused by the chamber tube 111 in the captured image is and how much the error is by comparing the first image in the open position of the chamber tube 111 and the second image in the closed position of the chamber tube 111. As a non-limiting example, the controller 140 may use an image analysis module to analyze or determine a difference between the first image and the second image. As a non-limiting example, the image analysis module may be configured to generate a comparison result between images by using differences in pixel values between input images. As a non-limiting example, the image analysis module may correspond to an artificial intelligence model that is pre-trained to output a difference in input images.

In one embodiment, the controller 140 may calculate an amount of impurity on the object to be processed 10 prior to the plasma processing of the object to be processed 10, and calculate an amount of impurity on the object to be processed 10 after the plasma processing of the object to be processed 10, using the correction value.

In an additional embodiment, the controller 140 may use the first image and/or the second image to predict or calculate an expected time period of the plasma processing procedure expected to process impurities of the object to be processed 10. The expected time period may have a positive correlation with the size of the impurity (or amount of impurity) within the first image and/or the second image. Based on the expected time period, the time period of the plasma processing procedure in S3 may be primarily determined. As will be described below, the controller 140 may determine whether to set the time period of the plasma processing to be shorter or longer than the expected time period by using an image (for example, a third image) captured within the primarily determined time period of the plasma processing procedure or an image (for example, a fourth or fifth image) captured after the time period ends.

In S3, the chamber tube 111 may be positioned in the closed position, and the chamber 110 may be in the closed state. The object to be processed 10 may be surface treated by plasma generated by the electrode 113. The inside of the chamber 110 may include the spatial distribution 20 of light generated by plasma. Plasma processing of the object to be processed 10 inside the chamber 110 may be started in S3.

In one embodiment, the controller 140 may change the imaging sensor 130 from the idle state (or from the second capturing state) to a third capturing state for capturing a third image representing plasma discharge for the object 10 at a time point between a start time point and an end time point of the plasma processing. Then, the controller 140 may acquire a third image from the imaging sensor 130 that has been changed to the third capturing state. In one embodiment, when the third image is acquired in S3, the imaging sensor 130 may be switched back to the idle state.

In one embodiment, the controller 140 may generate, from the third image, measurement results including the impurity removal state for the object to be processed 10, the plasma discharge characteristics, and the plasma reaction characteristics during the plasma processing procedure for the object to be processed 10. The controller 140 may control the plasma processing procedure of the object to be processed 10 by using the measurement results. For example, the measurement results may be generated using an artificial intelligence model pre-trained to take the third image as an input and to output measurement results including the impurity removal state for the object to be processed 10, the plasma discharge characteristics, and the plasma reaction characteristics. The artificial intelligence model may correspond to a model pre- trained based on a training dataset including images related to the object to be processed and labeling information indicating the impurity removal state, the plasma discharge characteristics, and the plasma reaction characteristics.

In one embodiment, the filter 133 may be moved to a position between the chamber 110 and the imaging sensor 130 by the imaging sensor driving unit 150. Alternatively, the imaging sensor 130 may include a separate imaging sensor with the filter 133 pre-mounted.

In one embodiment, the controller 140 may acquire an image including wavelength information for determining the plasma discharge characteristics and the plasma reaction characteristics through the filter 133.

In one embodiment, the controller 140 may determine whether to additionally perform a vacuum formation process for a plasma reaction in an isolation space that isolates the accommodated object to be processed 10 from an external environment, using at least one of the plasma discharge characteristics and the plasma reaction characteristics. A method for determining whether to additionally perform a vacuum formation process will be described with reference to the drawings below.

In S4, the chamber tube 111 may be positioned in the closed position, and the chamber 110 may be in the closed state. S4 may indicate a state in which the plasma processing of the object to be processed 10 has been completed.

In one embodiment, the controller 140 may change the imaging sensor 130 from the idle state (or from the third capturing state) to a fourth capturing state for capturing a fourth image corresponding to the object to be processed 10 when the chamber tube 111 is detected as being in the closed position after completion of the plasma processing. Then, the controller 140 may acquire a fourth image from the imaging sensor 130 that has been changed to the fourth capturing state. In one embodiment, when the fourth image is acquired in S4, the imaging sensor 130 may be switched back to the idle state.

In one embodiment, the controller 140 may generate a measurement result including the impurity removal state for the object to be processed 10 from the fourth image corresponding to the object to be processed 10. Then, the controller 140 may determine whether to resume or complete the plasma processing procedure of the object to be processed 10 using the measurement result. For example, the controller 140 may determine the impurity removal state of the object to be processed 10 by comparing the fourth image with at least one of the first image, the second image, and the third image. For example, the controller 140 may compare the fourth image with an image acquired before the acquisition of the fourth image, and generate a result regarding an impurity removal state or an impurity removal amount from the comparison result by using an image comparison module that compares images on a pixel-by-pixel basis or an artificial intelligence model pre-trained to output an image comparison result.

In one embodiment, whether to resume or complete the plasma processing procedure may be determined by the amount or state of the impurities contained in the fourth image. For example, when the amount of impurity included in the fourth image satisfies a predefined condition (for example, when there is no pixel value corresponding to the impurity), the plasma processing procedure may be completed, and when the amount of impurity included in the fourth image does not satisfy the predefined condition, the plasma processing procedure may be resumed. As described above, the fourth image can be used as a factor for determining whether to resume or complete the plasma processing procedure.

In another embodiment, whether to resume or complete the plasma processing procedure may be determined using a comparison result between the fourth image and other image(s) acquired before the acquisition of the fourth image.

In S5, the chamber tube 111 may be positioned in the open position, and the chamber 110 may be in an open state. S5 indicates a state in which the plasma processing procedure has been completed and the chamber tube 111 has moved from the closed position to the open position.

In one embodiment, the controller 140 may change the imaging sensor 130 from the idle state (or from the fourth capturing state) to a fifth capturing state for capturing a fifth image corresponding to the object to be processed 10 when the chamber tube 111 has moved from the closed position to the open position after completion of the plasma processing. Then, the controller 140 may acquire a fifth image from the imaging sensor 130 that has been changed to the fifth capturing state. In one embodiment, when the fourth image is acquired in S4, the imaging sensor 130 may be switched back to the idle state.

In one embodiment, the controller 140 may compare the impurities of the object to be processed 10 in the first image with the impurities of the object to be processed 10 in the fifth image, and generate a measurement result verifying the performance of the plasma processing of the object to be processed according to the comparison result.

In one embodiment, the controller 140 may compare the impurities of the object to be processed 10 in the second image with the impurities of the object to be processed 10 in the fifth image, and generate a measurement result verifying the performance of the plasma processing of the object to be processed according to the comparison result. In such a case, error information (for example, noise) acquired through the second image may be reflected in generating the measurement result.

In one embodiment, the controller 140 may dynamically determine a time period of the plasma processing for the object to be processed 10 within an isolation space that isolates the accommodated object to be processed 10 from an external environment, by using the image of the object to be processed 10 acquired by the imaging sensor 130.

Dynamically determining the time period of the plasma processing may refer to determining whether to extend or shorten a time period of the plasma processing, and specifically how much to extend or shorten the time period, according to the amount of impurity included in the acquired image and/or the amount of impurity calculated by comparing a plurality of acquired images and/or the amount of change in the amount of impurity. For example, since a reaction such as inflammation caused by impurities may occur if impurities of 10 micrometers or more remain on the object to be processed clinically, the plasma processing device 100 may stop the plasma processing procedure if the amount of impurity becomes less than 10 micrometers. For example, the plasma processing device 100 may control a length of the time period during which the object to be processed 10 is plasma-processed, by using the amount of impurity or the amount of change in the amount of impurity on the third image and/or the fourth image. For example, the plasma processing device 100 may control a length of the time period during which the object to be processed 10 is plasma-processed, by using the amount of impurity or the amount of change in the amount of impurity acquired as a result of comparing the fifth image with the first image and/or the second image.

In one embodiment, the plasma processing device 100 may perform a noise removal process to remove noise caused by the surface of the chamber tube 111 and/or the imaging sensor 130 in order to accurately measure an absolute value of the amount of impurity and the amount of change in the amount of impurity. That is, in order to perform the noise removal process, the plasma processing device 100 may generate a correction value through images acquired in S1 and S2 in respective states in which the object to be processed (or the target object) is present or absent and/or in which the tube is present or absent. As S3 progresses in a state in which the controller 140 is calibrated through the correction value, the technical effect can be achieved in which the plasma processing device 100 can provide accurate plasma processing performance by accurately acquiring the absolute value of the amount of impurity and the amount of change in the amount of impurity.

In one embodiment, the plasma processing device 100 may perform at least one of the listed processes S1 to S5 in order to measure the initial impurity absolute value according to the features of the object to be processed (for example, implant model-specific characteristics).

In one embodiment, through the listed processes S1 to S5, a technical effect can be achieved in which the plasma processing device 100 can reduce errors related to image quality deviation and temporal variation according to the type of the imaging sensor 130.

In one embodiment, the plasma processing device 100 can build quality data according to the characteristics of the object to be processed (for example, implant manufacturer-specific characteristics) by storing the images and impurity absolute values acquired through the listed processes S1 to S5. In addition, a technical effect can be achieved in which data obtained based on this can be used to generate training data for an artificial intelligence model and to train the artificial intelligence model so that the artificial intelligence model can accurately infer impurity according to characteristics of the object to be processed.

Throughout the present specification, the terms artificial intelligence model, computational model, neural network, network function, and neural network may be used interchangeably.

The neural network may generally be composed of a set of interconnected computational units, which may be referred to as nodes. These nodes may also be referred to as neurons. The neural network is configured to include at least one node. The nodes (or neurons) that constitute a neural network may be interconnected by one or more links.

In the neural network, one or more nodes connected through the link may relatively form a relationship between an input node and an output node. Concepts of the input node and the output node are relative and a predetermined node which has the relationship of the output node with respect to one node may have the relationship of the input node in the relationship with another node and vice versa. As described above, the relationship of the output node to the input node may be generated based on the link. One or more output nodes may be connected to one input node through the link and vice versa.

In the relationship of the input node and the output node connected through one link, a value of data of the output node may be determined based on data input in the input node. Here, a link connecting the input node and the output node to each other may have a weight. The weight may be variable, and the weight may be varied by a user or an algorithm in order for the neural network to perform a desired function. For example, when one or more input nodes are mutually connected to one output node by the respective links, the output node may determine an output node value based on values input to the input nodes connected with the output node and the weights set to the links corresponding to the respective input nodes.

As described above, in the neural network, one or more nodes are connected to each other through one or more links to form the input node and output node relationship in the neural network. A characteristic of the neural network may be determined according to the number of nodes, the number of links, correlations between the nodes and the links, and values of the weights granted to the respective links. For example, when the same number of nodes and links exist and two neural networks in which the weight values of the links are different from each other exist, it may be recognized that two neural networks are different from each other.

The neural network may be constituted by a set of one or more nodes. A subset of the nodes constituting the neural network may constitute a layer. Some of the nodes constituting the neural network may constitute one layer based on the distances from the initial input node. For example, a set of nodes of which distance from the initial input node is n may constitute n layers. The distance from the initial input node may be defined by the minimum number of links which should be passed from the initial input node up to the corresponding node. However, definition of the layer is predetermined for description and the order of the layer in the neural network may be defined by a method different from the aforementioned method. For example, the layers of the nodes may be defined by the distance from a final output node.

In one embodiment of the present disclosure, a set of neurons or nodes may be defined as the expression "layer."

The initial input node may mean one or more nodes in which data is directly input without passing through the links in the relationships with other nodes among the nodes in the neural network. Alternatively, in the neural network, in the relationship between the nodes based on the link, the initial input node may mean nodes which do not have other input nodes connected through the links. Similarly thereto, the final output node may mean one or more nodes which do not have the output node in the relationship with other nodes among the nodes in the neural network. Further, a hidden node may mean not the initial input node and the final output node but the nodes constituting the neural network.

In the neural network according to an exemplary embodiment of the present disclosure, the number of nodes of the input layer may be the same as the number of nodes of the output layer, and the neural network may be a neural network of a type in which the number of nodes decreases and then, increases again from the input layer to the hidden layer. In addition, in the neural network according to another exemplary embodiment of the present disclosure, the number of nodes of the input layer may be smaller than the number of nodes of the output layer, and the neural network may be a neural network of a type in which the number of nodes decreases from the input layer to the hidden layer. In addition, in the neural network according to yet another exemplary embodiment of the present disclosure, the number of nodes of the input layer may be larger than the number of nodes of the output layer, and the neural network may be a neural network of a type in which the number of nodes increases from the input layer to the hidden layer. The neural network according to still yet another exemplary embodiment of the present disclosure may be a neural network of a type in which the neural networks are combined.

The deep neural network (DNN), which is an example of the artificial intelligence model, may mean a neural network including a plurality of hidden layers other than the input layer and the output layer. When the deep neural network is used, the latent structures of data may be identified. The deep neural networks may include convolutional neural network (CNN), recurrent neural network (RNN), autoencoder, generative adversarial network (GAN), restricted Boltzmann Machine (RBM), deep belief network (DBN), Q network, U network, Siamese networks, and the like. The description of the deep neural network described above is just an example and the present disclosure is not limited thereto.

The artificial intelligence model of the present disclosure may be expressed by a network structure of an arbitrary structure described above, including the input layer, the hidden layer, and the output layer.

The neural network that may be used in an artificial intelligence model in the present disclosure may be trained in at least one scheme of supervised learning, unsupervised learning, semi-supervised learning, reinforcement learning, federated learning for distributed deep learning, or incremental learning. The training of the neural network may be a process of applying knowledge for the neural network to perform a specific operation to the neural network.

The neural network may be trained in a direction of minimizing an error of an output. The training of the neural network is a process of repeatedly inputting training data to the neural network, calculating an error between an output of the neural network for the training data and a target, and updating weights of respective nodes of the neural network by backpropagating the error of the neural network from an output layer to an input layer of the neural network in a direction of reducing the error. In the case of supervised learning, training data in which a correct answer is labeled for each training data (that is, labeled training data) is used, and in the case of unsupervised learning, a correct answer may not be labeled for each training data. That is, for example, in the case of supervised learning for data classification, training data may be data in which a category is labeled for each training data. Labeled training data is input to the neural network, and an error may be calculated by comparing an output (category) of the neural network with a label of the training data.

As another example, in the case of unsupervised learning for data classification, an error may be calculated by comparing training data serving as an input with an output of the neural network. The calculated error is backpropagated in a backward direction (that is, from an output layer toward an input layer) in the neural network, and connection weights of respective nodes of each layer of the neural network may be updated according to the backpropagation. An amount of change in the connection weight of each node that is updated may be determined according to a learning rate. The calculation of the neural network for the input data and the backpropagation of the error may constitute a learning cycle (epoch). The learning rate may be applied differently according to the number of repetitions of the learning cycle of the neural network. For example, in an early stage of the training of the neural network, a high learning rate may be used to allow the neural network to quickly secure a certain level of performance to increase efficiency, and in a later stage of the training, a low learning rate may be used to increase accuracy.

In the training of a neural network, training data is generally a subset of actual data (that is, data to be processed using the trained neural network), and therefore, there may exist learning cycles in which an error for the training data decreases but an error for the actual data increases. Overfitting is a phenomenon in which an error for actual data increases due to excessive training on the training data. For example, a phenomenon in which a neural network that has learned a cat by being shown a yellow cat does not recognize a cat when seeing a cat other than a yellow cat may be a type of overfitting. Overfitting may act as a cause of increasing an error of a machine learning algorithm. Various optimization methods may be used to prevent such overfitting. To prevent overfitting, methods such as increasing training data, regularization, dropout in which a part of nodes of a network is deactivated in a process of training, and use of a batch normalization layer may be applied.

According to one embodiment of the present disclosure, a computer-readable medium is disclosed, which stores a data structure. The above-described data structure may be stored in the memory of the plasma processing device 100 in the present disclosure, may be executed by the processor of the plasma processing device 100, and may be transmitted and received by the network unit of the plasma processing device 100.

The data structure may refer to organization, management, and storage of data that enable efficient access to and modification of data. The data structure may refer to the organization of data for solving a specific problem (for example, searching data, storing data, or modifying data in the shortest time). The data structure may also be defined as physical or logical relationships among data elements designed to support a specific data processing function. The logical relationships among data elements may include connection relationships among user-defined data elements. The physical relationships among data elements may include actual relationships among data elements physically stored in a computer-readable storage medium (for example, a permanent storage device). The data structure may specifically include a set of data, relationships among data, and functions or instructions that can be applied to the data. Through an effectively designed data structure, a computing device may perform computations while using resources of the computing device at a minimum. Specifically, a computing devices may increase efficiency of computation, reading, insertion, deletion, comparison, exchange, and searching through an effectively designed data structure.

A data structure may be classified into a linear data structure and a nonlinear data structure according to a form of the data structure. The linear data structure may be a structure in which only one data is connected after one data. The linear data structure may include a list, a stack, a queue, and a deque. The list may refer to a series of data sets in which an order exists internally. The list may include a linked list. The linked list may be a data structure in which data is connected in a manner in which each data has a pointer and is connected in a line. In the linked list, the pointer may include connection information with next or previous data. The linked list may be expressed as a singly linked list, a doubly linked list, or a circular linked list according to a form of the linked list. The stack may be a data arrangement structure in which data can be accessed in a limited manner. The stack may be a linear data structure in which data can be processed (for example, insertion or deletion) only at one end of the data structure. Data stored in the stack may be a data structure in which data exits faster as it is entered later (LIFO-Last in First Out). The queue may be a data arrangement structure in which data can be accessed in a limited manner, and, unlike a stack, may be a data structure in which data exits later as it is stored later (FIFO-First in First Out). The deque may be a data structure in which data can be processed at both ends of the data structure.

The nonlinear data structure can be a structure in which multiple data are connected after one data. The nonlinear data structure may include a graph data structure. The graph data structure may be defined by vertices and edges, and an edge may include a line connecting two different vertices. The graph data structure may include a tree data structure. The tree data structure may be a data structure in which there is only one path connecting two different vertices among multiple vertices included in a tree. In other words, the tree data structure may be a data structure that does not form a loop in the graph data structure.

Throughout the present specification, the terms artificial intelligence model, computational model, neural network, network function, and neural network may be used interchangeably. Below, the term "neural network" is used uniformly. The data structure may include a neural network. The data structure including the neural network may be stored in a computer-readable medium. The data structure including the neural network may also include preprocessed data for processing by the neural network, data input to the neural network, weights of the neural network, hyperparameters of the neural network, data acquired from the neural network, activation functions associated with respective nodes or layers of the neural network, a loss function for training the neural network, and the like. The data structure including the neural network may include any components among the above-disclosed configurations. That is, the data structure including the neural network may be configured to include preprocessed data for processing by the neural network, data input to the neural network, weights of the neural network, hyperparameters of the neural network, data acquired from the neural network, activation functions associated with respective nodes or layers of the neural network, a loss function for training the neural network, or all or any combination thereof. In addition to the configurations described above, the data structure including the neural network may include any other information that determines characteristics of the neural network. Additionally, the data structure may include any form of data used in or generated during the computational process of the neural network, and is not limited to the above. The computer-readable medium may include a computer-readable recording medium and/or a computer-readable transmission medium. The neural network may generally be composed of a set of interconnected computational units, which may be referred to as nodes. These nodes may also be referred to as neurons. The neural network is configured to include at least one node.

The data structure may include data that is input to the neural network. The data structure including data that is input to the neural network may be stored in a computer-readable medium. The data that is input to the neural network may include training data that is input during a neural network training process and/or input data that is input to a trained neural network. The data that is input to the neural network may include data that has undergone pre-processing and/or data intended for pre-processing. The pre-processing may include a data processing procedure for inputting data into the neural network. Therefore, the data structure may include data intended for pre-processing and data generated through pre-processing. The above-described data structure is only an example and the present disclosure is not limited thereto.

The data structure may include a weight of a neural network. (In the present specification, a weight and a parameter may be used interchangeably.) The data structure including the weight of the neural network may be stored in a computer-readable medium. The neural network may include a plurality of weights. The weight may be variable, and the weight may be varied by a user or an algorithm in order for the neural network to perform a desired function. For example, when one or more input nodes are mutually connected to one output node by the respective links, the output node may determine a data value output from an output node based on values input to the input nodes connected with the output node and the weights set to the links corresponding to the respective input nodes. The above-described data structure is only an example and the present disclosure is not limited thereto.

As a non-limiting example, the weights may include a weight that is varied during a neural network training process and/or a weight after neural network training has been completed. The weight that is varied during a neural network training process may include a weight at the start of a learning cycle and/or a weight that is varied during the learning cycle. The weight after neural network training has been completed may include a weight after the training cycle has been completed. Therefore, the data structure including the weight of the neural network may include a data structure including the weight that is varied during the neural network training process and/or the weight after neural network training has been completed. Therefore, the above-described weights and/or combinations of the respective weights are regarded as included in the data structure including the weight of the neural network. The above-described data structure is only an example and the present disclosure is not limited thereto.

The data structure including the weight of the neural network may be stored in a computer-readable storage medium (for example, a memory, a hard disk) after going through a serialization process. The serialization may be a process of converting a data structure into a form that can be stored on the same or a different computing device and later reconstructed for use. The computing device may serialize the data structure to transmit and receive data over a network. A data structure including a weight of a serialized neural network may be reconstructed on the same computing device or a different computing device through deserialization. The data structure including the weight of the neural network is not limited to serialization. Furthermore, the data structure including the weight of the neural network may include a data structure (for example, B-Tree, Trie, m-way search tree, AVL tree, or Red-Black Tree in a nonlinear data structure) for increasing computational efficiency while using resources of a computing device at a minimum. The above-described matter is only an example and the present disclosure is not limited thereto.

The data structure may include hyper-parameters of the neural network. The data structure including the hyperparameters of the neural network may be stored in a computer-readable medium. The hyperparameter may be a variable that is varied by a user. The hyperparameter may include, for example, a learning rate, a cost function, the number of repetitions of the learning cycle, weight initialization (for example, setting a range of weight values to be subjected to weight initialization), and the number of hidden units (for example, the number of hidden layers, the number of nodes in the hidden layer). The above-described data structure is only an example and the present disclosure is not limited thereto.

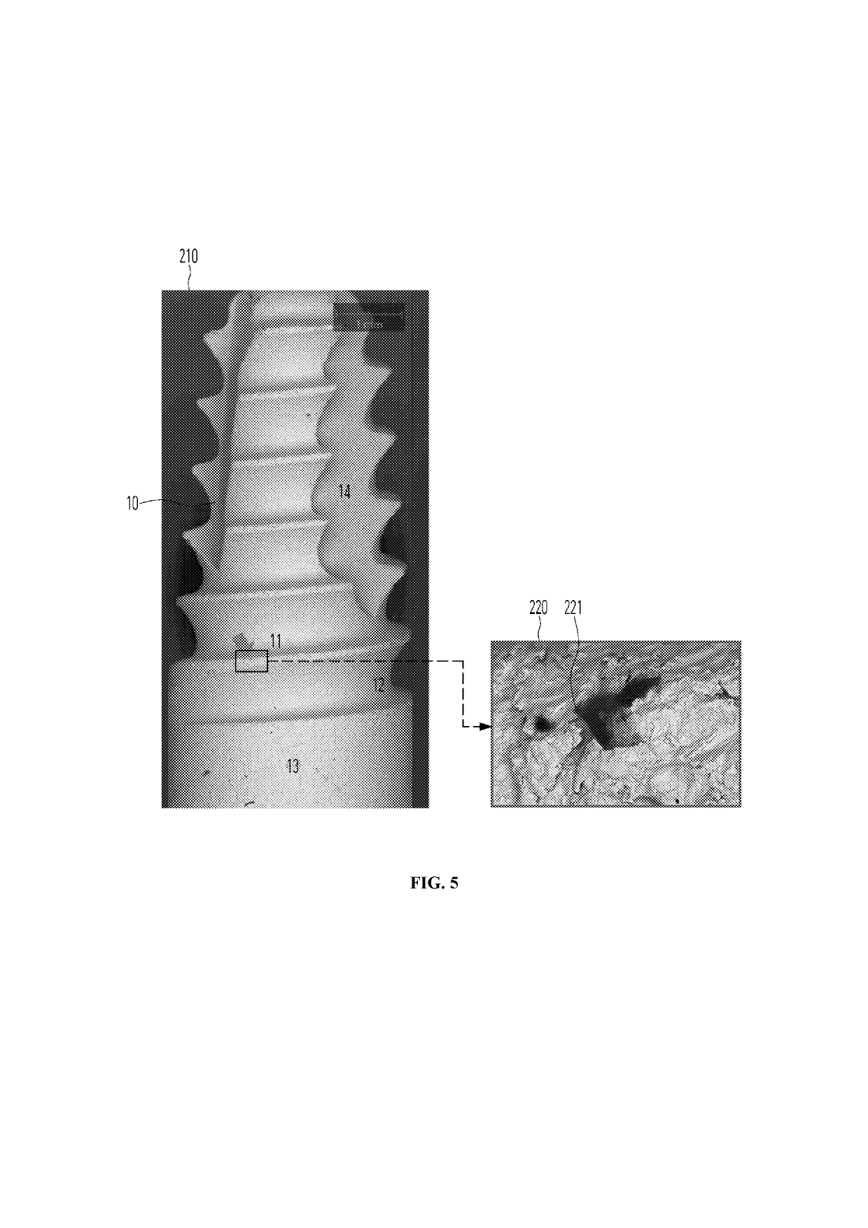

FIG. 5 is a view for illustrating an example of an image acquired from the plasma processing device according to one embodiment of the present disclosure.

In one embodiment, the controller 130 may include a pre-trained object detection model to detect the object to be processed 10. The object detection model may be included in the category of artificial intelligence models described above. The object detection model may correspond to an artificial intelligence model pre-trained to output location information for a predetermined object (for example, an impurity) and/or class information for the impurity on an input image. The controller 130 may acquire a first target image 210 including the object to be processed 10 from the first imaging sensor 131, and determine a target region 221 in the first target image 210 from the first target image 210 by using an object detection model. For example, the target region 221 may correspond to an impurity presented on the object to be processed 10. In one embodiment, the object detection model may correspond to an artificial intelligence model pre-trained to take the first target image 210 as an input and to output a result corresponding to reference number 11 (for example, segmentation for an impurity and/or a bounding box for an impurity).

In an additional embodiment, the object detection model may correspond to an artificial intelligence model pre-trained to take the first target image 210 as an input and to generate an output 220 that is an enlarged view of the target region 221 in order to more accurately identify an impurity in the first target image 210.

In one embodiment, the object detection model may be pre-trained to detect a full image of the object to be processed 10, one surface 14 of the object to be processed, grooves 12 of the object to be processed, threads 11 of the object to be processed, and a root 13 of the object to be processed.

In one embodiment, the object detection model may be pre-trained to detect a position of the object to be processed 10. For example, the position may include an upper portion, a middle portion, and a lower portion.

In one embodiment, the controller 140 may determine a position of an impurity in the object to be processed 10 for presentation to a user.

In one embodiment, the image may be in a state in which the position of the object to be processed 10 is difficult to visually confirm due to limitations in resolution, and the like. In this case, the controller 140 may determine a specific position (for example, at least one of an upper portion, a middle portion, and a lower portion) by using the object-detection model, without detecting and measuring an impurity over the full image, and may determine the presence or absence of an impurity at the specific position to determine the position of the impurity in the object to be processed (10).

In one embodiment, the object detection model may be pre-trained to detect, according to classification criteria of the object to be processed 10 (for example, a brand, a model, a size, a shape, and the like), a full image of the object to be processed 10, one surface 14 of the object to be processed, grooves 12 of the object to be processed, threads 11 of the object to be processed, and a root 13 of the object to be processed, which correspond to the respective classification criteria.

In one embodiment, the plasma processing device 100 may perform a plasma processing procedure for the object to be processed 10 corresponding to a specific classification criterion by storing and managing data such as impurity measurement results and learning results of the object detection model and reflecting previously stored data.

In one embodiment, the controller 140 may arbitrarily select, as a target region, at least one of one surface 14 of the object to be processed, the groove 12 of the object to be processed, the thread 11 of the object to be processed, and the root 13 of the object to be processed, which are detected in the first target image 210. Then, the controller 140 may measure a change in the impurity at a position selected as the target region.

In one embodiment, the object detection model may determine a target region including an impurity in the first target image.

In one embodiment, the controller 140 may determine a placement position of the imaging sensor 130 in the plasma processing device 100 or an orientation angle of the placed imaging sensor 130 by using the object-detection result.

In one embodiment, the controller 140 may control and determine operation (for example, capturing) timings and operation positions of a plurality of imaging sensors.

In one embodiment, the controller 140 may determine a placement position of the second imaging sensor 132 in the plasma processing device 10 or an orientation angle of the placed second imaging sensor 132, based on the target region 11. For example, the controller 140 may determine a placement position and an orientation angle of the second imaging sensor 132 such that the second imaging sensor is directed toward the target region 221. For example, the controller 140 may use the second imaging sensor 132 in order to acquire an enlarged image of the target region 11 of the target image 210 acquired from the first imaging sensor. The controller 140 may determine a capturing time point and/or a capturing position (or orientation) of the second imaging sensor 132, based on a capturing result of the first imaging sensor 131. The controller 140 may determine the capturing time point and/or the capturing position (for example, placement position and/or orientation angle) of the second imaging sensor 132, based on the target image 210. For example, when the target image 210 is acquired, the controller 140 may determine to switch the second imaging sensor 132 from the idle state to the capturing state.

In one embodiment, when the placement position and orientation angle of the second imaging sensor 132 are determined, the second imaging sensor 132 may acquire the second target image 220 including the target region 221. The controller 140 may acquire the target image 210 by controlling the capturing of the first imaging sensor 131, determine the target region 11 in the target image 210, move the second imaging sensor 132 by using the position of the target region 11, and allow the moved second imaging sensor 132 to capture an enlarged image 220 of the target region 11.

In one embodiment, the second imaging sensor 132 may acquire a plurality of second target images 220 during the plasma processing procedure. The controller 140 may control the plasma processing procedure according to changes in the target region 221 in the second target image 220.

In one embodiment, the imaging sensor 130 may acquire an image including a surface corresponding to 180 degrees out of 360 degrees with respect to the object to be processed 10. In one embodiment, the controller 140 may measure an impurity on a surface corresponding to 180 degrees at a surface corresponding to a specific angle (for example, 150 degrees) in the image. The controller 140 may determine, in terms of cost and time efficiency of the plasma processing procedure, that an impurity included in an image corresponding to a specific angle acquired from the imaging sensor 130 represents an overall impurity corresponding to the object to be processed 10. The controller 140 may perform the plasma processing procedure by using an amount of impurity at a specific position of the object to be processed 10 included in the image and a change in the amount of impurity.

In one embodiment, the imaging sensor 130 may be provided on each of the left and right sides of the plasma processing device 100. In this case, the controller 140 may generate a full image by using a left 180-degree image and a right 180-degree image of the object to be processed 10 acquired from each imaging sensor 130. The controller 140 may also use the generated full image to detect an impurity.

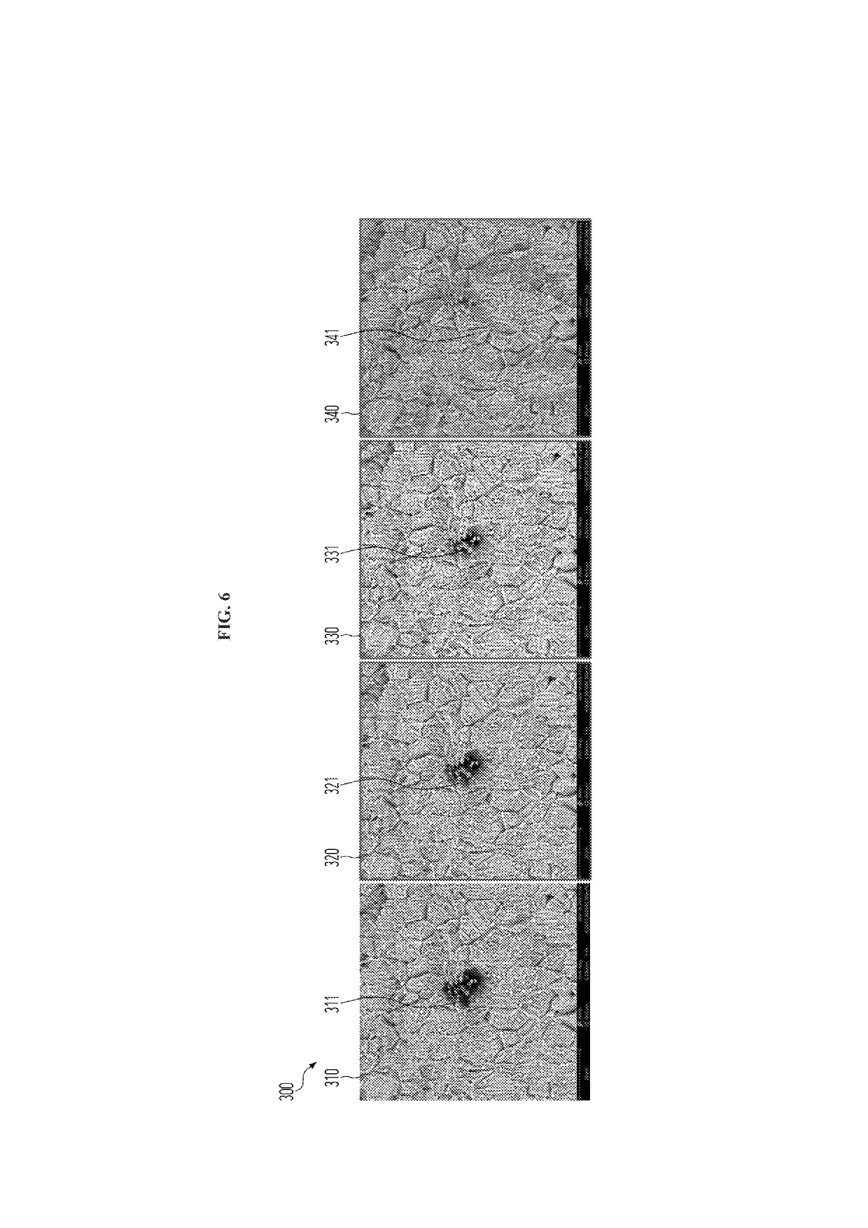

In one embodiment, a method of controlling the plasma processing procedure according to a change in the target region 221 in the second target image 220 of the controller 140 will be described below with reference to FIG. 6.

FIG. 6 is a view for illustrating an example of an image acquired from the plasma processing device during a surface treatment process by the plasma processing device according to one embodiment of the present disclosure.

In one embodiment, the controller 140 may determine a change in an amount of impurity according to surface treatment from images 300 per time unit acquired based on a predetermined time unit reference. In one embodiment, the images 300 per time unit may correspond to the second target image 220, with reference to FIG. 5.

In one embodiment, the time unit may be a unit of seconds, such as 10 seconds or 20 seconds, but is not limited thereto, and may be set and changed as needed by a user.

In one embodiment, the number of the images 300 per time unit is not limited to the number shown in FIG. 5, and the number of images acquired from the start point to the end point of the plasma processing procedure is not limited.

In one embodiment, the images 300 per time unit may include a first time point image 310, a second time point image 320, a third time point image 330, and a fourth time point image 340 acquired in order of predetermined time units. For example, the first to fourth time points may be included in a time period between the start point of the plasma process and the end point of the plasma process.

In one embodiment, the first time point image 310 may correspond to an image acquired at a time point prior to the start of the plasma processing procedure. The first time point image 310 may include a first impurity image 311 corresponding to an initial amount of impurity before surface treatment of the object to be processed.

In one embodiment, the second time point image 320 may correspond to an image acquired at a time point after a first time unit from the start of the plasma processing procedure. The second time point image 320 may include a second impurity image 321, in which an amount of impurity is relatively smaller than that of the first impurity image 311, as surface treatment is performed on the impurity.

In one embodiment, the third time point image 330 may correspond to an image acquired at a time point after two time units from the start of the plasma processing procedure. The third time point image 330 may include a third impurity image 331, in which an amount of impurity is relatively smaller than that of the second impurity image 321, as surface treatment is performed on the impurity.

In one embodiment, the fourth time point image 340 may correspond to an image acquired at a time point after three time units from the start of the plasma processing procedure. The fourth time point image 340 may include a fourth impurity image 341, in which an amount of impurity is relatively smaller than that of the third impurity image 331, as surface treatment is performed on the impurity. In one embodiment, the fourth time point image 340 may correspond to an image acquired upon completion of the plasma processing procedure or at a time point thereafter. The fourth impurity image 341 may correspond to a state in which the impurity is completely removed.

In one embodiment, the controller 140 may generate a measurement result including the impurity removal state for the object to be processed 10 from the images per time unit corresponding to the object to be processed 10. Then, the controller 140 may determine whether to resume or complete the plasma processing procedure of the object to be processed 10 using the measurement result.

In one embodiment, the controller 140 may determine whether to resume or complete the plasma processing procedure, depending on whether an impurity is included in the image acquired upon completion of the plasma processing procedure or at a time point thereafter. For example, when an impurity is included in the image acquired upon completion of the plasma processing procedure or at a time point thereafter, the controller 140 may determine that the plasma processing procedure is to be resumed. Alternatively, when an impurity is not included in the image acquired upon completion of the plasma processing procedure or at a time point thereafter, the controller 140 may determine that the plasma processing procedure has been completed. Based on the size and/or amount of impurity present in the image, the controller 140 may automatically determine a completion time point of the plasma processing procedure. For example, the plasma processing procedure may have a positive correlation with the size of the impurity in the target image.

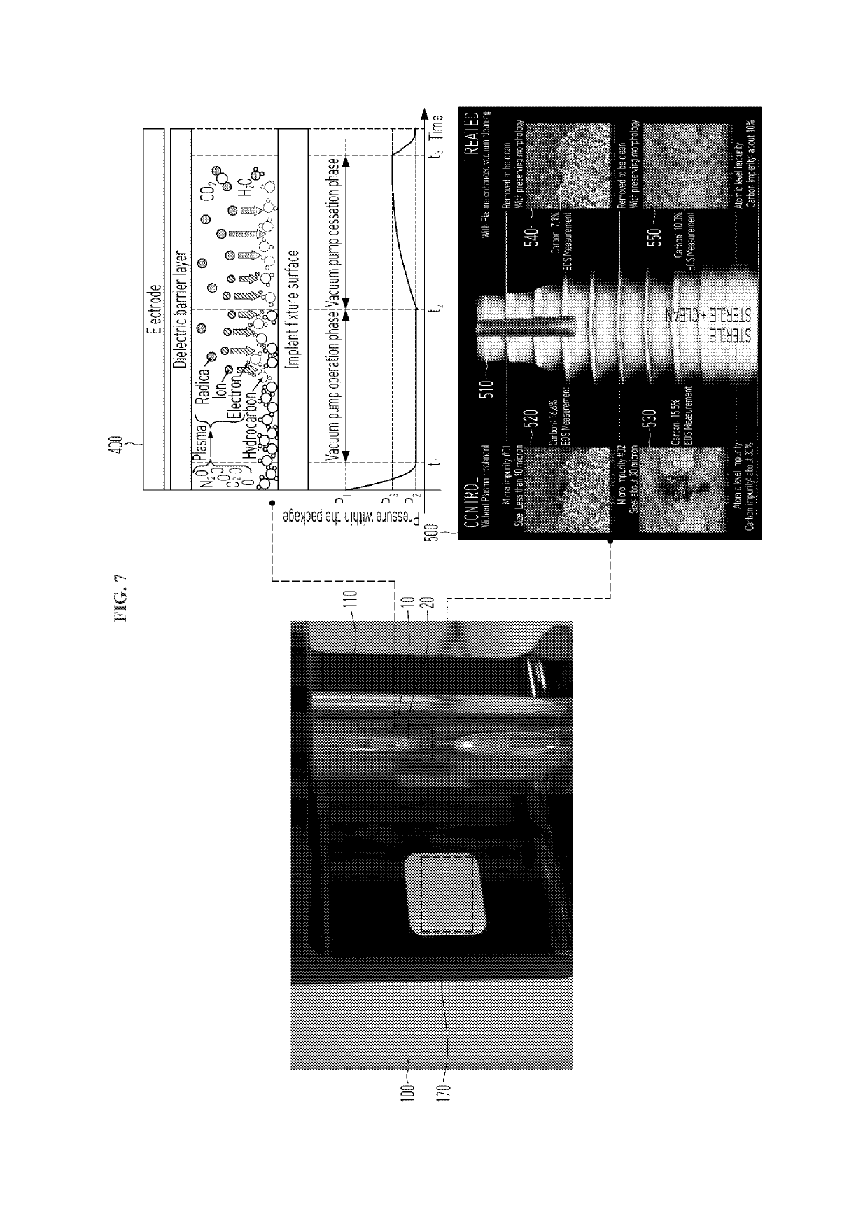

FIG. 7 is a view for illustrating an example of the plasma processing device according to one embodiment of the present disclosure and objects output by the plasma processing device.

Referring to FIG. 7, the plasma processing device 100 may output a user interface (UI) corresponding to an image acquired from the imaging sensor 130 and a result generated from the image, through the display 170.

In one embodiment, the display 170 may output an image acquired from the imaging sensor 130.

In one embodiment, the display 170 may output a result of processing the image acquired from the imaging sensor 130.

In one embodiment, the plasma processing device 100 may visually display the plasma processing procedure of an actual object to be processed 10 through the chamber tube 111 that is at least partially transparent, and output information related to the object to be processed 10 and/or the plasma processing procedure acquired during the plasma processing procedure, through the display 170.

In one embodiment, the UI may include numerical values corresponding to plasma discharge characteristics and reaction characteristics and/or a numerical value corresponding to impurity residue corresponding to an amount of impurity.

In one embodiment, the controller 140 may generate an object detection result 500 corresponding to the object to be processed 10 from the image received from the imaging sensor 130 by using a pre-learned object detection model.

In one embodiment, the detection result 500 may include a full image 510 of the object to be processed 10, and a first impurity image 520 and a second impurity image 530 included in the object to be processed. The first impurity image 520 and the second impurity image 530 may be images acquired at time points before surface treatment of the object to be processed 10.

In one embodiment, the detection result 500 may include an image corresponding to a time point after surface treatment has been performed on the object to be processed 10. For example, the detection result 500 may include a first region 540 and a second region 550 from which impurities have been removed, corresponding to the first impurity image 520 and the second impurity image 530.

In one embodiment, the detection result 500 may correspond to an image that compares the first impurity image 520 and the second impurity image 530 corresponding to a time point before surface treatment of the object to be processed 10 and a first region 540 and a second region 550 corresponding to a time point after the surface treatment of the object to be processed 10, based on the full image 510 of the object to be processed 10.

In one embodiment, the display 170 may display a first object representing the object to be processed 10 (corresponding to the full image 510 of the object to be processed 10), a second object representing a surface of the object to be processed before plasma treatment (including the first impurity image 520 and the second impurity image 530), and a third object representing a surface of the object to be processed after plasma treatment (including the first region 540 and the second region 550). The display 170 may connect at least one of the second object and the third object to the first object by displaying a position of at least one of the second object and the third object on the first object.

In one embodiment, the controller 140 may determine whether to additionally perform a vacuum formation process for a plasma reaction in an isolation space that isolates the accommodated object to be processed 10 from an external environment, using at least one of the plasma discharge characteristics and the plasma reaction characteristics. For example, a medium state 400 in the isolation space, which corresponds to a type of gas, a gas concentration, and a gas pressure included in the isolation space according to the plasma processing procedure, may be varied. When the medium state 400 is varied, a color of light corresponding to the plasma, a distribution region of light, and the like may change relatively. Accordingly, the medium state 400 in the isolation space may be uniformly maintained according to the vacuum formation process of the present disclosure in order to accurately acquire the absolute color of light and the distribution region of light according to the amount of impurity.

In one embodiment, the controller 140 may calculate the medium state 400 in the isolation space and output it through the display 170. The user can determine whether to perform the vacuum formation process by visually checking the medium condition 400 in the isolation space through the display 170 and manually controlling the vacuum pump 180 and/or the controller 140.

During the plasma processing procedure of the object to be processed 10, measurement results including the impurity removal state for the object to be processed 10, the plasma discharge characteristics, and the plasma reaction characteristics may be generated. Then, the controller 140 may control the plasma processing procedure for the object to be processed 10 by using the measurement results.

In one embodiment, the plasma discharge characteristics may refer to a spatial distribution of light intensity generated on a surface of the object to be processed, from an image perspective. The plasma reaction characteristics may refer to the wavelength of light and the corresponding color (for example, RGB values in an image).

In one embodiment, the plasma discharge characteristics may be determined by a plurality of images acquired in time units for a region in which plasma is discharged (for example, corresponding to a distribution of plasma generated in a chamber). The controller 140 may calculate an amount of change and a rate of change per hour of a region in which plasma is discharged, based on a plurality of images acquired in time units. Additionally, the plasma discharge characteristics may correspond to the amount of change and/or the rate of change of the region in which plasma is discharged. For example, when the amount of change per hour of the region in which plasma is discharged is small and thus the rate of change of the region in which plasma is discharged is low, i.e., when it takes a long time for plasma to spread uniformly in a space (for example, the chamber 110), the controller 140 may determine that the initial vacuum at the time of plasma discharge is insufficient and/or that the amount of impurity on the surface of the object to be processed is large. The controller 140 may control the plasma processing device 100 to stop the plasma processing procedure and/or to re-perform the vacuum formation process by using the determination result.

In one embodiment, the plasma reaction characteristics are characteristics of light generated from the plasma, which may correspond to RGB values of the image and/or wavelength values acquired through the filter 133.

In one embodiment, when the RGB values of an image are used, the image may include a red color if the object to be processed has many impurities. If the plasma processing procedure time is long, the image may include a white color. Correspondingly, when the filter 133 is used, the filter 133 may enable acquisition of light of a wavelength corresponding to a red color if the object to be processed has many impurities, and may enable acquisition of light of a wavelength corresponding to a white color if the plasma processing procedure time is long.

In one embodiment, the plasma 20 generated during the plasma processing procedure may be expressed in different colors for a region close to the object to be processed 10 and a region far from the object to be processed. For example, the plasma 20 may appear purple in a region close to the object to be processed 10, and may appear in a color (for example, red) changed due to a chemical reaction caused by the object to be processed 10 as the plasma 20 becomes farther from the object to be processed 10.

In one embodiment, the plasma 20 generated during the plasma processing procedure may be expressed in different light brightness for a region close to the object to be processed 10 and a region far from the object to be processed. For example, the plasma 20 may appear in a color close to white in a region close to the object to be processed 10 because the brightness of light is strong in the region, and may appear in a color (for example, gray) whose brightness becomes darker due to a chemical reaction caused by the object to be processed 10 as the plasma 20 becomes farther from the object to be processed 10.

In one embodiment, light of a specific wavelength may be emitted depending on the chemical reaction that occurs during the plasma processing procedure (for example, CHₓ + O₂ → CO₂ + H₂O). For example, the intensity of light of a particular wavelength may be high in an early stage of the plasma processing procedure and then decrease over time (as impurities of the object to be processed are removed). The controller 140 may control the plasma processing procedure time and/or the intensity of the plasma according to changes in the intensity of light of a specific wavelength. For example, when the intensity of light is below a predefined reference intensity, the controller 140 may control the plasma processing device 100 to stop the plasma processing procedure.

In one embodiment, the controller 140 may acquire a chemical characteristic or state of the object to be processed 10 in the chamber 110 by measuring a specific wavelength of light, because the specific wavelength of light may also be generated in a chemical reaction with the object to be processed 10 (for example, TiOₓ + O₂ → TiO_{y}), rather than in a reaction with impurities.

In one embodiment, the plasma processing device 100 may achieve a technical effect in which a user can perform control, such as starting or stopping the plasma processing procedure, by displaying the plasma processing procedure and/or surface treatment performance for the object to be processed on the display 170.

In one embodiment, the plasma processing device 100 may store data corresponding to the plasma processing procedure and/or surface treatment performance for the object to be processed, and transmit the stored data to an external device (for example, a printer, a user terminal, a server, and the like). The data transmitted to the external device may be output by a printer, or managed by a user terminal and/or a server, for example. When managed on the server, additional analysis of the data may be performed by the server, and the server may use the data to generate and provide additional analysis results, such as customer management and product problem resolution methods. In one embodiment, the plasma processing device 100 may transmit data (for example, images acquired in real time) generated while the plasma processing procedure is performed on the object to be processed to a server in real time.

In one embodiment, the plasma processing device 100 may receive data managed and analyzed through a server to update a software program included in the controller 140. For example, the analyzed data may be customer service information including a method of performing a processing procedure for the object to be processed, to be provided to the user.

In one embodiment, the plasma processing device 100 may determine a type of impurity based on the size and shape of the impurity. The size and shape of the impurity may be determined based on a color value (for example, RGB values) that the impurity has depending on characteristics of light (for example, brightness, intensity, temperature, and the like) in an image acquired from the imaging sensor 130, using the number and a distribution of pixels corresponding to the impurity.

In one embodiment, the plasma discharge characteristics may also be determined from the number and distribution of pixels of color values corresponding to the plasma phenomena included in the image.

In one embodiment, the plasma reaction characteristics may be determined, in a predefined image, based on an average color value of an entire plasma generation region and on differences in relative color values. And/or, the plasma reaction characteristics may be determined from the intensity of light in an image corresponding to a specific wavelength acquired through the specific filter 133.

In one embodiment, the type of impurity may be determined according to a cause of impurity generation, such as an impurity generated during a production process of the object to be processed and an impurity generated during a handling process by a user.

In one embodiment, the plasma processing device 100 may perform an accurate and efficient plasma processing procedure as data on the object to be processed and/or impurities are accumulated. Specifically, the plasma processing device 100 may determine a plasma processing procedure corresponding to the type of impurity and perform the determined plasma processing procedure.

In one embodiment, the plasma processing device 100 may measure surface treatment performance (for example, performance such as time taken to remove impurities and energy efficiency) for the object to be processed according to the type of impurity, by using plasma reaction characteristics acquired according to the type of impurity.

In one embodiment, the plasma processing device 100 may determine chemical characteristics of an impurity by using a light source. For example, the plasma processing device 100 may, by using a light source that irradiates light of a specific wavelength, acquire chemical characteristics of the object to be processed and/or an impurity corresponding to the specific wavelength, and may determine a type of the object to be processed and/or the impurity according to the chemical characteristics of the object to be processed and/or the impurity.

In one embodiment, the plasma processing device 100 may acquire additional data regarding impurity distributions for respective implant models based on accumulated data of the object to be processed and/or an impurity. The plasma processing device 100 may, by using the additional data, control the imaging sensor 130 such that more images are acquired in portions in which an impurity is found with high probability according to the type of the object to be processed.

According to an embodiment of the present disclosure, a technical effect can be achieved in which the plasma processing device 100 can absolutely calculate the amount of impurity presented on the object to be processed and a processing procedure according to the amount of impurity, as the space in the chamber 110 is uniformly maintained in a vacuum state and an error in an image generated by the chamber tube 111 is corrected.

According to an embodiment of the present disclosure, a technical effect can be achieved in which the plasma processing device 100 can present an optimal plasma processing procedure to a user according to characteristics of each object to be processed, by acquiring, storing, and managing data according to classification criteria of an acquired object to be processed (for example, an implant).

### [List of Reference Numerals]

10: object to be processed

20: distribution of plasma and/or light generated by plasma

100: plasma processing device

110: chamber 111: chamber tube 112: ground electrode 113: electrode

120: power supply

130: imaging sensor

131: first imaging sensor 132: second imaging sensor 133: filter

140: controller

150: imaging sensor driving unit

160: chamber tube driving unit

170: display:

180: vacuum pump

210: first target image 220: second target image 221: target region

300: images per time unit

310: first time point image 311: first impurity image

320: second time point image 321: second impurity image

330: third time point image 331: third impurity image

340: fourth time point image 341: fourth impurity image

400: medium state in isolation space

500: detection result

510: full image of object to be processed 10 520: first impurity image

530: second impurity image 540: first region 550: second region

What is claimed is:

1. A plasma processing device for acquiring an image of an object to be processed, comprising:
a chamber configured to accommodate the object to be processed;
a power supply configured to generate plasma inside the chamber;
an imaging sensor configured to acquire a surface image of the object to be processed; and
a controller configured to control a capturing operation of the imaging sensor for acquiring the surface image of the object to be processed, according to an operation of the plasma processing device, and
wherein the controller determines a time period of plasma processing for the accommodated object to be processed, using one or more surface images corresponding to the object to be processed.

2. The plasma processing device of claim 1,
wherein the chamber includes a drivable chamber tube,
at least one surface of the chamber has a light-transmitting properties, and
the imaging sensor is provided outside the chamber to acquire the surface image of the object to be processed in the chamber.

3. The plasma processing device of claim 1, wherein the imaging sensor includes:
a filter configured to transmit light of a predetermined wavelength;
a light source configured to irradiate light toward the object to be processed to enhance contrast of the object to be processed being captured, the light source irradiating light corresponding to a predetermined wavelength;
a first imaging sensor configured to acquire a first target image including the object to be processed; and
a second imaging sensor configured to acquire a second target image that is an enlarged view of a target region in the first target image.

4. The plasma processing device of claim 1, further comprising:
a driving unit configured to move the imaging sensor to a target location so that the imaging sensor acquires a target image including the object to be processed; and
a display configured to display the acquired surface image or an analysis result of the surface image by using the controller.

5. The plasma processing device of claim 1, wherein the controller controls the capturing operation of the imaging sensor such that at least one pre-image of the object to be processed at a time point before plasma is generated by the power supply and at least one post-image of the object to be processed that has been plasma-processed by the plasma generated by the power supply are respectively acquired.

6. The plasma processing device of claim 1, wherein the chamber is provided such that one surface of the chamber is at least partially open, and the controller controls the capturing operation of the imaging sensor such that at least one image at a time point before the opening of the chamber and at least one image at a time point after the opening of the chamber are respectively acquired.

7. The plasma processing device of claim 1, wherein the controller controls the capturing operation of the imaging sensor such that images per time unit are acquired based on a predetermined time unit, during a process in which the plasma generated by the power supply is plasma-processing the object to be processed, and controls a plasma processing procedure of the object to be processed according to the generation of the plasma, based on the images per time unit.

8. The plasma processing device of claim 6, wherein the controller generates a correction value for compensating for an error in surface measurement for the object to be processed, which occurs due to physical damage to the chamber or contamination of the chamber, by comparing a surface of the object to be processed in an image at the time point before the opening of the chamber and a surface of the object to be processed in an image at the time point after the opening of the chamber, and calculates an amount of impurity on the object to be processed prior to plasma processing of the object to be processed using the correction value.

9. The plasma processing device of claim 7, wherein the controller generates a measurement result including an impurity removal state for the object to be processed, plasma discharge characteristics, and plasma reaction characteristics during the plasma processing procedure of the object to be processed, from the images per time unit acquired based on the predetermined time unit, and controls the plasma processing procedure of the object to be processed using the measurement result.

10. The plasma processing device of claim 9, wherein the controller determines whether to additionally perform a vacuum formation process for a plasma reaction in an isolation space that isolates the accommodated object to be processed from an external environment, using at least one of the plasma discharge characteristics and the plasma reaction characteristics.

11. The plasma processing device of claim 10, wherein the controller generates a measurement result including an impurity removal state for the object to be processed from the images per time unit corresponding to the object to be processed, and determines whether to resume or complete the plasma processing procedure of the object to be processed using the measurement result.

12. The plasma processing device of claim 1, wherein the imaging sensor acquires a plurality of images corresponding to the object to be processed during a time period of the plasma processing for the object to be processed in the chamber, and the controller determines an amount of change in a surface of the object to be processed according to the plasma processing using the plurality of images, and dynamically determines a time period of the plasma processing for the object to be processed within an isolation space that isolates the accommodated object to be processed from an external environment, using the determined amount of change in the surface.

13. The plasma processing device of claim 1, wherein the imaging sensor includes a first imaging sensor and a second imaging sensor, the first imaging sensor and the second imaging sensor are disposed at mutually opposing positions with respect to an isolation space that isolates the accommodated object to be processed from an external environment within the plasma processing device, to acquire a front image and a rear image of the object to be processed, and the controller integrates the front image and the rear image to generate a measurement result regarding the object to be processed.

14. The plasma processing device of claim 13, wherein the controller determines a target region in the first target image from the first target image including the object to be processed acquired from the first imaging sensor, using a pretrained object detection model, and determines a placement location of the second imaging sensor within the plasma processing device or an orientation angle of the placed second imaging sensor, based on the target region.

15. The plasma processing device of claim 1, wherein the controller generates an object detection result corresponding to the object to be processed from an image received from the imaging sensor, using a pretrained object detection model, and determines a placement location of the imaging sensor within the plasma processing device or an orientation angle of the placed imaging sensor, using the object detection result.

16. The plasma processing device of claim 7, wherein the controller determines plasma discharge characteristics indicating an area where plasma is discharged within an image, using the image received from the imaging sensor during the plasma processing procedure for the object to be processed, and determines an amount of impurity presented on the object to be processed or determines that a vacuum condition of the plasma processing is not satisfied, based on a time taken for a spatial distribution of light by the plasma to expand within the image, and wherein the plasma discharge characteristics are determined based on the spatial distribution of light by the plasma generated on a surface of the object to be processed within the image.

17. The plasma processing device of claim 1, wherein the controller determines plasma reaction characteristics indicating a characteristic of light generated by the plasma, using a color value corresponding to the plasma in the image received from the imaging sensor during the plasma processing procedure for the object to be processed.

18. The plasma processing device of claim 1, wherein the imaging sensor includes a filter configured to extract light corresponding to a predetermined wavelength to determine plasma reaction characteristics of the plasma processing of the object to be processed and to determine chemical features of a surface of the object to be processed, and the controller determines plasma reaction characteristics indicating a characteristic of light generated by the plasma, using a wavelength acquired through the filter during the plasma processing procedure for the object to be processed.

19. The plasma processing device of claim 1, wherein the imaging sensor includes a thermal imaging camera, and the controller controls the thermal imaging camera acquiring a temperature and a temperature distribution of the object to be processed during the plasma processing procedure for the object to be processed.

20. The plasma processing device of claim 11, further comprising:
a display configured to output the measurement result;
wherein the display displays a first object representing the object to be processed, a second object representing a surface of the object to be processed prior to the plasma processing, and a third object representing a surface of the object to be processed after the plasma processing, and connects at least one of the second object and the third object with the first object by displaying a location of the at least one of the second object and the third object on the first object.
